(19) United States
(12) Patent Application Publication
(10) Pub. No.: US 2025/0125155 A1
(43) Pub. Date: Apr. 17, 2025

(54) ATOMIC LAYER ETCHING USING BORON TRICHLORIDE

(71) Applicant: Lam Research Corporation, Fremont, CA (US)

(72) Inventors: Andreas Fischer, Castro Valley, CA (US); Aaron Lynn Routzahn, Fremont, CA (US); Thorsten Bernd Lill, Kalaheo, HI (US)

(21) Appl. No.: 18/688,739

(22) PCT Filed: Sep. 6, 2022
(86) PCT No.: PCT/US2022/075996

§ 371 Date: Mar. 1, 2024

Related U.S. Application Data
(60) Provisional application No. 63/260,945, filed on Sep. 7, 2021.

(51) Int. Cl. H01L 21/311; H01L 21/67

(52) U.S. Cl. CPC H01L 21/31122; H01L 21/67069

(57) ABSTRACT

Methods and apparatuses for etching materials using a boron trichloride during atomic layer etching are provided. The method comprises providing a wafer to a processing chamber, the wafer having an oxygen-containing material, exposing the oxygen-containing material to a halogen-containing gas to form a modified oxygen-containing layer on a surface of the wafer, and exposing the modified oxygen-containing layer to the boron trichloride to remove the modified layer from the surface of the wafer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor device fabrication involves formation of structures that can be sensitive to etching processes, such as exposure to energetic species, and sensitive to oxidation, moisture, and additional exposure to energetic species after etching. As a result, some structures undergo post-etching processes to address damage from etching and exposure to the environment. However, some methods of post-etching processing, and the corresponding apparatuses, may not be unable to sufficiently address the damage and exposures to the structures and may further damage the structures.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing wafers, the method including: providing a wafer to a processing chamber, the wafer having an oxygen-containing material; exposing the oxygen-containing material to a halogen-containing gas to form a modified oxygen-containing layer on a surface of the wafer; and exposing the modified oxygen-containing layer to boron trichloride to remove the modified layer from the surface of the wafer.

In various embodiments, exposing the modified oxygen-containing layer is performed in a plasma-less environment.

In various embodiments, exposing the modified oxygen-containing layer forms a volatile oxychloride.

In various embodiments, exposing the modified oxygen-containing layer causes a ligand exchange.

In various embodiments, exposing the oxygen-containing material to the halogen-containing gas and exposing the modified oxygen-containing layer are performed in alternating pulses by atomic layer etching.

In any of the above embodiments, the modified oxygen-containing layer may include boron oxide.

In any of the above embodiments, the oxygen-containing material may be a metal oxide. For example, in some embodiments, the metal oxide includes a metal selected from the group consisting of aluminum, silicon, germanium, antimony, indium, zirconium, selenium, tin, gallium, zinc, molybdenum, hafnium, tellurium, and combinations thereof.

In any of the above embodiments, the oxygen-containing material may be selected from the group consisting of aluminum oxide and indium gallium zinc oxide.

In any of the above embodiments, the oxygen-containing material may be selected from the group consisting of zirconium oxide, hafnium oxide, and hafnium zirconium oxide.

In any of the above embodiments, the oxygen-containing material may be a carbide or nitride formed by oxidizing the carbide or nitride.

In any of the above embodiments, the oxygen-containing material may be doped.

In various embodiments, exposing the oxygen-containing material to be etched to the halogen-containing gas includes igniting the halogen-containing gas to form a halogen-containing plasma. For example, in some embodiments, the oxygen-containing material includes a metal. In various embodiments, the halogen-containing plasma is generated remotely.

In various embodiments, the halogen-containing plasma is generated in situ.

In various embodiments, the halogen-containing gas includes fluorine.

In various embodiments, the halogen-containing gas includes nitrogen trifluoride.

Another aspect involves a method for processing wafers, the method including: providing a wafer to a processing chamber, the wafer having an oxygen-containing material; exposing the oxygen-containing material to a halogen-containing gas to form a modified oxygen-containing layer on a surface of the wafer; and exposing the modified layer to a boron-and-chlorine-containing gas to remove the modified oxygen-containing layer from the surface of the wafer.

In various embodiments, exposing the modified oxygen-containing layer is performed in a plasma-less environment.

In various embodiments, exposing the modified oxygen-containing layer forms a volatile oxychloride.

In various embodiments, exposing the modified oxygen-containing layer causes a ligand exchange.

In various embodiments, exposing the oxygen-containing material to the halogen-containing gas and exposing the modified oxygen-containing layer are performed in alternating pulses by atomic layer etching.

In any of the above embodiments, the modified oxygen-containing layer may include boron oxide.

In any of the above embodiments, the oxygen-containing material may be a metal oxide. For example, in some embodiments, the metal oxide includes a metal selected from the group consisting of aluminum, silicon, germanium, antimony, indium, zirconium, selenium, tin, gallium, zinc, molybdenum, hafnium, tellurium, and combinations thereof.

In any of the above embodiments, the oxygen-containing material may be selected from the group consisting of aluminum oxide and indium gallium zinc oxide.

In any of the above embodiments, the oxygen-containing material may be selected from the group consisting of zirconium oxide, hafnium oxide, and hafnium zirconium oxide.

In any of the above embodiments, the oxygen-containing material may be a carbide or nitride formed by oxidizing the carbide or nitride.

In any of the above embodiments, the oxygen-containing material may be doped.

In various embodiments, exposing the oxygen-containing material to be etched to the halogen-containing gas includes igniting the halogen-containing gas to form a halogen-containing plasma. For example, in some embodiments, the oxygen-containing material includes a metal.

In various embodiments, the halogen-containing plasma is generated remotely.

In various embodiments, the halogen-containing plasma is generated in situ.

In various embodiments, the halogen-containing gas includes fluorine.

In various embodiments, the halogen-containing gas includes nitrogen trifluoride.

Another aspect involves a method for processing wafers, the method: providing a wafer to a processing chamber, the wafer having a material to be etched; exposing the material to be etched to a halogen-containing gas to form a modified layer on a surface of the wafer; and exposing the modified layer to boron-and-chlorine-containing gas in a plasma-less environment to remove the modified layer from the surface of the wafer.

In various embodiments, the material to be etched is selected from the group consisting of oxides, carbides, nitrides, doped oxides, doped carbides, doped nitrides, and combinations thereof.

In various embodiments, the boron-and-chlorine-containing gas is boron trichloride.

In various embodiments, the material to be etched includes oxygen.

In various embodiments, the material to be etched is a dielectric.

In various embodiments, exposing the material to be etched to the halogen-containing gas includes igniting the halogen-containing gas to form a halogen-containing plasma. For example, in some embodiments, the material to be etched includes a metal. In some embodiments, the material to be etched is oxidized prior to being exposed to the halogen-containing plasma.

In various embodiments, the halogen-containing plasma is generated remotely.

In various embodiments, the halogen-containing plasma is generated in situ.

In various embodiments, the halogen-containing gas includes fluorine.

In various embodiments, the halogen-containing gas includes nitrogen trifluoride.

Another embodiments involves a method for processing wafers, the method including: providing a wafer to a processing chamber, the wafer having a metal oxide; exposing the metal oxide to hydrogen fluoride or nitrogen trifluoride to form a modified metal oxide layer on a surface of the wafer; and exposing the modified layer to boron trichloride in a plasma-less environment to remove the modified metal oxide layer from the surface of the wafer.

In various embodiments, the metal oxide is selected from the group consisting of aluminum oxide, hafnium oxide, and indium gallium zinc oxide.

In various embodiments, exposing the metal oxide to the hydrogen fluoride or nitrogen trifluoride includes igniting the hydrogen fluoride or nitrogen trifluoride to form a fluorine-containing plasma. For example, in some embodiments, the fluorine-containing plasma is generated remotely. In some embodiments, the fluorine-containing plasma is generated in situ.

In various embodiments, forming the modified layer and removing the modified metal oxide layer are performed without breaking vacuum.

In various embodiments, forming the modified metal oxide layer and removing the modified metal oxide layer are performed at a temperature greater than about 170° C.

Another embodiment involves a method for processing wafers, the method including: providing a wafer to a processing chamber, the wafer having a tungsten-free material; exposing the tungsten-free material to be etched to a fluorine-containing gas to form a modified tungsten-free layer on a surface of the wafer; and exposing the modified tungsten-free layer to a non-pyrophoric chlorine-containing gas in a plasma-less environment to remove the modified tungsten-free layer from the surface of the wafer.

Another embodiments involves an apparatus for semiconductor processing, the apparatus including: a first processing chamber that includes a first interior and a first processing station having a first wafer support configured to support a wafer in the first interior, and a first wafer heating unit configured to heat the wafer supported by the first wafer support; a process gas unit configured to flow: a first chemical species including fluorine onto the wafer at the first processing station in the first processing chamber, and boron trichloride onto the wafer at the first processing station in the first processing chamber; and a controller with instructions that are configured to: cause a wafer to be provided to the first processing station in the first processing chamber, the wafer having a layer of a chalcogenide material, cause the first wafer heating unit to heat the wafer to a first temperature, and cause etching of a material on the wafer by modifying a surface of the material by causing the process gas unit to flow the first chemical species onto the wafer at the first processing station of the first processing chamber to create a modified layer while the wafer is at the first temperature, and removing the modified layer, without using a plasma, by causing the process gas unit to flow the boron trichloride onto the wafer at the first processing station of the first processing chamber.

These and other aspects are described further below with reference to the drawings.

### BRIEF DESCRIPTION OF THE DRAWINGS

FIG. 1 depicts an example schematic illustration of atomic layer etching in accordance with certain disclosed embodiments.

FIG. 2 depicts an example process flow diagram for performing operations in accordance with certain disclosed embodiments.

FIGS. 3A through 3C depict example gas flow sequences according to certain disclosed embodiments.

FIG. 4 schematically shows an embodiment of a process station that may be used to deposit material in accordance with certain disclosed embodiments.

FIG. 5 depicts an example of a wafer processing chamber for etching materials according to the certain disclosed embodiments.

FIG. 6 depicts a cross-sectional side view of an example apparatus in accordance with certain disclosed embodiments.

FIG. 7 depicts a top view of a wafer heater with a plurality LEDs.

FIG. 8 depicts a first example processing apparatus according to certain disclosed embodiments.

FIG. 9 depicts a second example processing apparatus according to certain disclosed embodiments.

FIG. 10 shows etch rate per atomic layer etching cycle using boron trichloride with hydrogen fluoride and results after exposure to boron trichloride only in accordance with certain disclosed embodiments.

FIG. 11A shows relative etch amounts of hafnium oxide, aluminum oxide, silicon, silicon oxide, silicon nitride, titanium nitride, and tungsten for an ALE etch process.

FIG. 11B shows relative etch amounts of hafnium oxide, aluminum oxide, silicon, silicon oxide, silicon nitride, titanium nitride, and tungsten for an ALE etch process performed in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often involve etching of various materials, such as metal oxides. Some materials may be susceptible to damage when exposed to plasma-based etching processes. However, some thermal processes may not sufficiently etch certain materials, or in some cases, a tool's temperature limitations may limit the applicability of certain thermal processes. In some cases, thermal or plasma-less processes may be used to etch materials, but some processes may be difficult to control, particularly for etching specific thicknesses of material or for achieving selectivity to other exposed surfaces during etching.

Provided herein are techniques and apparatuses for etching a variety of materials using boron trichloride. Certain disclosed embodiments are directed to etching a variety of materials using a boron-and-chlorine-containing gas. Certain disclosed embodiments are directed to atomic layer etching using boron trichloride as a removal gas in a plasma-less environment. Boron trichloride can be used as a substitute for dimethylaluminum chloride (DMAC) which can be used to etch a variety of materials including but not limited to aluminum oxide, hafnium oxide, zirconium oxide, hafnium silicon oxide, silicon-doped hafnium oxide, indium gallium zinc oxide, hafnium zirconium oxide, alloyed oxide made from hafnium and zirconium, and chalcogenide material such as germanium, selenium, and tellurium. Boron trichloride has an additional advantage in that it is a less expensive gas that is commonly available, does not need to be volatilized, and is not pyrophoric.

Certain disclosed embodiments use a boron-and-chlorine-containing gas, such as boron trichloride, to perform atomic layer etching thermally, or plasma-less atomic layer etching. Certain disclosed embodiments may be used for a variety of etching applications, including but not limited to etching one or more layers of chalcogenide material, etching indium gallium zinc oxide, and etching metal oxides such as aluminum oxide, hafnium oxide, or zirconium oxide.

Boron trichloride can be used as a removal gas where the modification gas or species used to modify a surface of the substrate forms a bond on the surface of the substrate that causes the surface to be thermally removed when exposed to boron trichloride in a thermodynamically favorable reaction. Boron trichloride can be used to isotropically remove material by atomic layer etching.

As explained in greater detail below, thermal atomic layer etching may modify a surface of a layer of material by flowing a first chemical species having a halogen onto the wafer to create a modified layer of material, and remove the modified layer of material, without using a plasma, by flowing a second chemical species having boron and chlorine, such as boron trichloride onto the wafer which may be performed by a ligand exchange mechanism.

Atomic layer etching (“ALE”) can be used to etch materials in accordance with certain disclosed embodiments. ALE processes remove thin layers of material using sequential self-limiting reactions. Generally, an ALE cycle is the minimum set of operations used to perform an etch process one time, such as etching a monolayer. The result of one ALE cycle is that at least some of a film layer on a wafer surface is etched. Typically, an ALE cycle includes a modification operation to form a reactive layer, followed by a removal operation to remove or etch only this reactive layer. The cycle may include certain ancillary operations such as removing one of the reactants or byproducts, as well as a cleaning operation to remove residues that have built up on surfaces of the processing chamber. Generally, a cycle contains one instance of a unique sequence of operations.

As an example, an ALE cycle may include the following operations: (i) delivery of a first process gas that is a reactant gas, (ii) purging of the reactant gas from the chamber, (iii) delivery of a second process gas that is a removal gas and an optional plasma, and (iv) purging of the chamber. The modification operation (item (ii) above) generally forms a thin, reactive surface layer with a thickness less than the un-modified material, such as one, two, or three, atomic layers thick, for instance, or less than a whole atomic layer in one cycle.

The etching processes described herein may rely upon chemical reactions in conjunction with maintaining the wafer at a particular temperature or temperature range to drive chemical reactions in the modification and/or the removal operations which may be considered “thermal ALE” or “thermal etching”. In some embodiments, the thermal etching or thermal ALE may be considered an isotropic etch. In some embodiments, one or more layers of the wafer may be modified with chemical adsorption (hereinafter “chemisorption”), not with a plasma, while the wafer is maintained at a first temperature, after which the one or more modified layers of the wafer may be removed with desorption, not with a plasma, while the wafer is at a second temperature. Some implementations may optionally use a plasma during the modification operation and not during the removal operation. In some embodiments the first and second temperatures may be the same, while in some other embodiments they may be different than each other.

Chemisorption and desorption are temperature dependent chemical reactions that may occur in separate temperature regimes, may occur in partially overlapping temperature regimes, or may occur in the same temperature regime. Because of this, some of the thermal etching techniques described herein maintain the temperature of the wafer at the same, or substantially the same (e.g., within about 10% or 5% of each other), temperature during the modification and removal operations. Some other embodiments modulate the temperature of the wafer between the modification and removal operations in order to enable and utilize chemisorption that occurs at one temperature for the modification operation, and to enable and utilize desorption that occurs at a different temperature for the removal operation.

In some thermal etching processes provided herein, one or more surface layers of material are modified by chemisorption while the wafer is maintained at a first temperature; this may result in the creation of one or more modified surface layers of the wafer. The wafer includes layers of material and exposed surfaces that may be a uniform layer of material or may be a non-uniform layer that includes different molecules and elements. A first process gas with modifying molecules may be flowed onto the wafer that is maintained at the first temperature. In some embodiments, the modifying molecules may include a fluorine or a chlorine, as described below, in order to fluorinate or chlorinate molecules on the wafer. The first process gas may also include a carrier gas, such as nitrogen (N₂), argon (Ar), helium (He), and neon (Ne). This first temperature allows for chemisorption between the modifying molecules and at least some of the molecules in the exposed surface(s) of material.

The one or more modified surface layers may be removed while the wafer is maintained at the second temperature. In some embodiments, the second temperature alone may enable and cause desorption of the modified molecules from the wafer thereby removing the modified molecules from the wafer. In some embodiments, a second process gas with removal molecules may be flowed onto the wafer, including onto the exposed surfaces of the wafer. The second process gas may also include a carrier gas as described above. These removal molecules may react with the modified molecules to form a different volatile molecule, which may be considered a volatized molecule. This volatized molecule may in turn be removed from the wafer by desorption when the wafer is at the second temperature. In some embodiments, this flowing of the second process gas may be part of the removal operation or may be a separate operation that occurs before, after, or during the heating of the wafer.

In some embodiments, thermal ALE may be isotropic and thus non-directional. In some other embodiments thermal ALE is not isotropic when directional ions are used in the etching process, such as during the modification operation.

Other thermal etching may be performed in which the modifying and removal molecules are at least co-flowed onto the wafer, and thus the modification and removal operations at least partially overlap. One or more process gases containing both modifying molecules and removal molecules may be simultaneously flowed onto the wafer during such processing. In many implementations of this thermal etching, the modifying molecules and the removal molecules have limited to no adverse reaction with each other, such that they may be co-flowed onto the wafer. In some instances, this co-flow may occur for all of the etching while in other instances, the co-flow may only occur for a part of the etching. In some examples having only partially overlapping flows, the modifying molecules may be flowed onto the wafer before the removal molecules are flowed onto the wafer, after which both the modifying molecules and the removal molecules may be simultaneously flowed onto the wafer. In some instances, the flow of both the modifying molecules and the removal molecules may stop at substantially the same time (e.g., within about 10% or 5% of each other) while in other instances, the flow of modifying molecules may stop and the removal molecules may be flowed onto the wafer.

The techniques provided herein may also deposit one or more encapsulation materials onto the etched chalcogenide. This may include depositing encapsulation material using chemical vapor deposition (“CVD”), plasma-enhanced CVD (“PECVD”), or atomic layer deposition (“ALD”) in a processing chamber separate from the processing chamber in which etching is performed. Some embodiments may transfer the wafer between these processing chambers without exposing the wafer to atmospheric pressure such that the wafer remains at a vacuum pressure in both processing chambers and during transfer between the processing chambers. In some embodiments, a layer of a first encapsulation material may be deposited on the etched chalcogenide while the wafer remains in the processing chamber in which etching is performed, and the first encapsulation material may include an aluminum, such as aluminum oxide. After the first encapsulation material is deposited, the wafer may be transferred to another processing chamber where additional encapsulation material is deposited on the wafer.

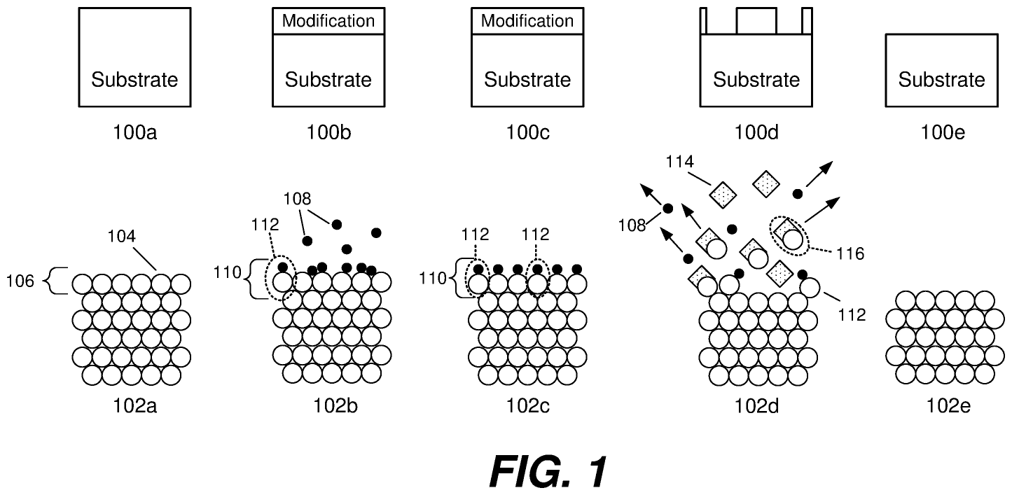

Some implementations of the described etching are further explained with FIG. 1 which depicts an example schematic illustration of atomic layer etching in accordance with disclosed embodiments. Diagrams 100a-100e show an ALE cycle. In 100a, the wafer with one or more layers of an oxygen-containing material to be etched is provided. In 100b, the surface of the oxygen-containing material is modified. In 100c, the next operation is prepared; this preparation may include flowing a second process gas or purging the chamber. In 100d, the wafer is exposed to the removal molecules which react with to the modified layer and cause it to desorb from, and therefore be removed from, the wafer. In 100e, the desired material has been removed.

In diagrams 102a-102e a single layer of oxygen-containing material is etched from a wafer. In 102a, the wafer is provided and it has one or more layers of oxygen-containing material 104, with each molecule represented as unshaded circles. The top layer of the oxygen-containing material may be considered a oxygen-containing material surface layer 106. In 102b, a first process gas with modifying molecules 108 (the solid black circles) that include a fluoride or chloride is introduced to the wafer which modifies the oxygen-containing material surface layer 106 to form a fluorinated oxygen-containing material or a chlorinated oxygen-containing material. The schematic in 102b shows that some of the modifying molecules 108 are adsorbed onto the molecules of the oxygen-containing material 104 of the oxygen-containing material surface layer 106 to create a modified surface layer 110 that includes modified molecules 112 (one modified molecule 112 is identified inside a dotted ellipse in 102b). As stated above, the modifying molecules 108 may be a species having a fluorine, such as hydrogen fluoride, or a species having a chloride, such as hydrogen chloride. For some thermal ALE techniques, this diagram 102b may occur while the wafer is maintained at the first temperature as described above, e.g., that enables chemisorption of the modifying molecule on the surface of the oxygen-containing material.

In diagram 102c, after the modified molecules 112 and the modified surface layer 110 have been created in 102b, the first process gas may be optionally purged from the chamber.

In diagram 102d, removal molecules 114 are introduced into the process chamber and in some embodiments, this may occur by flowing a second process gas having the second species, i.e., having the removal molecules 114, onto the wafer and the second species may include a compound having boron and chlorine, such as boron trichloride. Diagram 102d further illustrates that the removal molecules 114, shown as a shaded diamond, react with the fluorinated chalcogenide or the chlorinated oxygen-containing material, i.e., the modified molecules 112, which causes the oxygen-containing material 104 and the molecules 108 (which may be fluoride or chloride) to desorb from, and thus be removed from, the wafer. In some embodiments, the reaction between the removal molecules 114 and the modified molecules 112 causes the modifying molecules 108 to desorb from the wafer, and causes the removal molecules and the oxygen-containing material to form another compound 116, illustrated by a combination of the oxygen-containing material 104 unshaded circle and the removal molecule 114 shaded diamond, which desorbs from the wafer. In some other embodiments, not illustrated, the removal molecules and the modified molecules together form another compound that is caused to desorb from the wafer.

In some thermal ALE embodiments, this removal operation may be performed at a second temperature where desorption of the modified molecules 112 of the modified surface layer 110 from the wafer occurs; no plasma is utilized in these removal operations. In some embodiments, the second temperature is the same, or substantially the same (e.g., within about 10% or 5% of each other), as the first temperature. In other embodiments, the first and second temperatures may be different than each other and, in these embodiments, the temperature may be changed from the first temperature to the second temperature by either heating or cooling the wafer. In some instances, the temperature in one or more of the operations may be ramped up.

In 102e, the modified molecules 112, and therefore the modified surface layer 110, have been removed from the wafer.

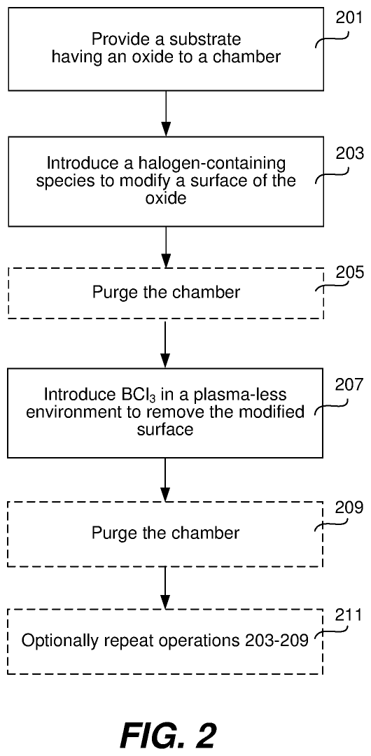

FIG. 2 depicts an example process flow diagram for performing operations in accordance with disclosed embodiments. In an operation 201, a wafer is provided to a processing chamber configured to performing etching of the wafer. The wafer may include a material to be etched. The material to be etched may be a dielectric material. The material to be etched may be an oxygen-containing material. The material to be etched may be a metal material. The material to be etched may be tungsten-free. The material to be etched may be a non-tungsten metal material. The material to be etched may be a tungsten-free metal material. The material to be etched may be an oxide. The material to be etched may be a semiconductor oxide. The material to be etched may be a semiconductor material such as silicon, silicon germanium, germanium, or combinations thereof. The material to be etched may be a metal oxide. The metal oxide may be a hafnium oxide, tungsten oxide, molybdenum oxide, aluminum oxide, zinc oxide, gallium oxide, zirconium oxide, indium oxide, tin oxide, selenium oxide, tellurium oxide, or combinations thereof. In some embodiments, the wafer includes a transition metal oxide.

The material to be etched may be formed by exposing a metal surface to an oxygen-containing reactant. In some embodiments, operation 201 includes exposing a metal surface to an oxygen-containing reactant. Example metal surfaces include hafnium, tungsten, molybdenum, aluminum, zinc, gallium, zirconium, indium, tin, selenium, tellurium, and others. In some embodiments, the metal surface includes a transition metal. In some embodiments, the metal surface includes elemental metal. Other materials include indium gallium arsenide (InGaAs), indium aluminum arsenide (InAlAs), indium phosphide (InP), and combinations thereof. In some embodiments, the metal surface includes a metalloid. In some embodiments, the wafer includes a chalcogenide. The chalcogenide may be any of those listed herein. In some implementations, the chalcogenide may be a phase change material, such as a germanium (Ge) antimony (Sb) tellurium (Te) (collectively “GST” or “GeSbTe”) material. This may also include n-doped GeSbTe compounds (N-GST), Sb₂Te, and Sb₂Te doped with Ag and In (AIST). As provided above, phase change materials are advantageous for use in forming memory devices because, for instance, the phase of a metal chalcogenide determines the bit state. In some embodiments, the chalcogenide may include those that do not change phase, such as an ovonic threshold switching (OTS) material which may include a compound with germanium, arsenic, and selenium (GeAsSe) or a compound containing germanium, antimony, selenium and nitrogen (GeSb,Se,N) and others.

In some embodiments, the material to be etched on the wafer is a non-oxide. The material to be etched may be a nitride. The material to be etched may be a carbide. The material to be etched may be a doped nitride. The material to be etched may be a doped carbide. The material to be etched may be a doped oxide. The material to be etched may include a dopant, such as but not limited to carbon.

During operation 201, after the wafer is provided to the chamber, the wafer may be heated to a first temperature which may be, as provided herein, considered both a specific temperature, or may be a temperature range. In some embodiments, the first temperature may be about 20° C. to about 500° C., about 20° C. to about 150° C., about 20° C. to about 80° C., about 20° C. to about 100° C., about 100° C. to about 450° C., about 100° C. to about 400° C., about 150° C. to about 400° C., about 200° C. to about 600° C., about 200° C. to about 500° C., about 200° C. to about 400° C., about 200° C. to about 350° C., or about 350° C. to about 500° C., or at least about 120° C., or less than about 170° C., for example. As discussed in more detail below, the wafer may be maintained at the first temperature during all, or substantially all (e.g., at least 80%, 90%, or 95%), of the etching, of the modification operation, and/or the removal operation.

In an operation 203, a halogen-containing species is introduced to the chamber. In various embodiments, in operation 203, an oxide surface is exposed to the halogen-containing species. In some embodiments, an oxide surface is exposed to a fluorine-containing species. In some embodiments, a metal oxide surface is exposed to a fluorine-containing species. In some embodiments, a metal oxide surface is exposed to nitrogen trifluoride. The halogen-containing species reacts with or modifies the surface of the wafer to form a modified surface. The modified surface may include one or more halogen end groups as a result of the reaction or modification. The halogen-containing species may be a halogen-containing gas or vaporized halogen-containing species. Examples include fluorine-containing species, such as a hydrogen fluoride, such as HF, a sulfur fluoride, such as sulfur tetrafluoride or sulfur hexafluoride or sulfuryl fluoride (SO₂F₂), a nitrogen fluoride such as nitrogen trifluoride (NF₃), and a xenon fluoride, such as xenon difluoride; and chlorine-containing species such as a hydrogen chloride, such as HCl, a sulfur chloride, such as sulfur dichloride or sulfur tetrachloride or sulfuryl chloride (SO₂Cl₂), or a nitrogen chloride such as trichloramine (NCl₃). The modification gas used is selected based on the thermodynamically favorable removal using a boron-and-chlorine-containing gas such as boron trichloride in operation 207. In some embodiments, the use of a fluorine species or chlorine species for modifying the surface of the layer of material to be etched results in a unique reactive compound that enables and allows for the removal of all the material when in the presence of the removal molecules because fluorine and chlorine bind very strongly to the surface and weaken the bonds to the underlayers. In some embodiments, the modification gas used is a fluorine-containing gas. The first chemical species may be flowed in vapor form onto the wafer and may be flowed as a part of a process gas that may optionally include a carrier gas such as nitrogen, argon, helium, or neon, for instance.

During operation 203, a surface of the layer of the oxide is modified, i.e., this operation represents the modification operation. Operation 203 includes flowing a first process gas that includes the first chemical species having a fluoride or chloride onto the wafer. Flowing the first chemical species onto the wafer modifies the surface of the layer of oxide and creates a layer of fluorinated material or fluorinated oxide that is uniquely capable of being removed by exposure to and reactions with boron trichloride. This first chemical species in the first process gas may be any of those provided herein, including one or more of the following non-limiting examples: a hydrogen fluoride, such as HF, a sulfur fluoride, such as sulfur tetrafluoride or sulfur hexafluoride or sulfuryl fluoride, a nitrogen fluoride such as nitrogen trifluoride, and a xenon fluoride, such as xenon difluoride, a hydrogen chloride, such as HCl, a sulfur chloride, such as sulfur dichloride or sulfur tetrachloride or sulfuryl chloride, or a nitrogen chloride such as trichloramine (NCl₃). The first process gas may also be flowed in vapor form onto the wafer and may be optionally include a carrier gas such as N₂, Ar, He, or Ne, for instance. The modification operation of operation 203 may be stopped by stopping the flow of the first process gas to the wafer.

In some embodiments, an activation energy may be provided to assist with overcoming the activation barrier for the modifying molecule to adsorb on the wafer. This activation energy may be provided with thermal energy, radical energy, and/or UV photons, in some instances, which may include heating the wafer and/or generating a plasma or photons. This adsorption of the modifying molecule onto the first material may be considered chemical adsorption or “chemisorption” which is an energy dependent (e.g., a temperature dependent) chemical reaction. For some thermal etching techniques, this chemisorption during the modification operation may only occur at a particular temperature range that enables the activation barrier of the molecules in the layer of material and the incoming modifying molecules to be overcome which allows for dissociation and chemical bonding between these molecules and an adsorbate in the modifying molecule. Outside of this temperature range, the chemisorption may not occur, or may occur at undesirable (e.g., slow) rates.

Accordingly, some implementations of operation 203 modify the surface layer of the oxide using only thermal activation energy, not a plasma. The first process gas is flowed onto the wafer that is maintained at the first temperature which provides the activation energy, and the oxide is modified by chemisorption to from the modified layer of the oxide. The first temperature may be any temperature or temperature range provided herein, such as about 20° C. to about 500° C., about 20° C. to about 150° C., about 20° C. to about 80° C., about 20° C. to about 100° C., about 100° C. to about 450° C., about 100° C. to about 400° C., about 150° C. to about 400° C., about 200° C. to about 600° C., about 200° C. to about 500° C., about 200° C. to about 350° C., or about 350° C. to about 500° C., or at least about 120° C., or less than about 170° C., for example. Additionally, the wafer may be maintained at the first temperature during all, or substantially all (e.g., at least 80%, 90%, or 95%), of the modification operation. The duration of the modification operation may be the duration for which modification of substantially all (e.g., at least 80%, 90%, or 95%) of desired exposed molecules on the wafer occurs. This may range from about 0.5 seconds to about 600 seconds, about 0.5 seconds to about 400 seconds, about 0.5 seconds to about 300 seconds, about 0.5 seconds to about 10 seconds, about 0.5 seconds to about 5 seconds, about 1 second to about 5 seconds, or about 5 seconds to about 300 seconds, for example.

In some embodiments, a plasma may be generated in operation 203 by igniting the halogen-containing species. The plasma may be generated in situ or remotely. In various embodiments, a plasma may be used when the material to be etched includes a metal. In various embodiments, a plasma may be used when the material to be etched is an oxidized metal.

In some implementations, ionic energy, such as from a plasma, may be used to drive the modification operation of operation 203. In some instances, a plasma may be ignited and a fluorine or a chlorine may react with the wafer or may be adsorbed onto the surface of the wafer. The species generated from a plasma can be generated directly by forming a plasma in the process chamber housing the wafer or they can be generated remotely in a process chamber that does not house the wafer, and can be supplied into the process chamber housing the wafer.

In an operation 205, the chamber may be optionally purged. Purging may be performed by pumping excess byproducts or gases out of the chamber or by flowing a purge gas such as an inert gas, or both.

In an operation 207, boron trichloride, or another boron-and-chlorine-containing gas, is introduced to the chamber in a plasma-less environment to remove the modified surface. The compound of the chemical species used in operation 207 reacts with the fluorinated material or chlorinated material to cause its elements to become volatile and desorb from the wafer. For example, this exchange reaction is energetically favorable and therefore the fluorinated material or chlorinated material is able to form volatile compounds with the compound through, for example, transfer of chlorine, or for example for etching chalcogenide material, through combining to form volatile germanium, antimony and tellurium compounds containing a combination of fluorides and chlorides. The boron trichloride may also be flowed in vapor form onto the wafer and may be flowed as a part of a process gas that may be optionally include a carrier gas that is inert to the reaction for removing the material; example carrier gases may include nitrogen, argon, helium, or neon, for instance. In some embodiments, boron trifluoride may be used instead of boron trichloride in operation 207. In some embodiments, other chemical species may be used instead of boron trifluoride or boron trichloride. Example chemical species may include a compound with a center atom that is aluminum, boron, silicon, or germanium, and with at least one chlorine atom. The selection of the species used in operation 207 may depend on the species and the surface modified in operation 203.

In some embodiments, operation 207 may be performed under various process conditions that enable such etching. In addition to the temperature ranges provided above, some implementations may maintain the wafer at a temperature of about 20° C. to about 500° C., about 20° C. to about 150° C., about 20° C. to about 80° C., about 20° C. to about 100° C., about 100° C. to about 450° C., about 100° C. to about 400° C., about 150° C. to about 400° C., about 200° C. to about 600° C., about 200° C. to about 500° C., about 200° C. to about 350° C., or about 350° C. to about 500° C., or at least about 120° C., or less than about 170° C., for example, during the etching. The etching may also be performed while the processing chamber is maintained at a pressure of about 10 millitorr (mTorr) to about 100 Torr, or about 20 millitorr to 760 Torr (1 atm), including about 20 mTorr to 600 mTorr, about 30 mTorr to 500 mTorr, and about 40 mTorr to 400 mTorr, as well as about 3 Torr to 8 Torr, about 4 Torr to 8 Torr, 2 Torr to 10 Torr, and 100 Torr to 760 Torr, for example. As discussed in more detail below, some implementations perform the etching at substantially constant process conditions (e.g., with minor deviations, such as deviations of about 10% or 5% of the set conditions), while other implementations may vary one or more of the process conditions during the etching.

In operation 207, modified oxide, i.e., the fluorinated oxide or chlorinated oxide, is removed from the wafer. Operation 207 includes flowing boron trichloride onto the wafer in a plasma-less environment. As described herein, boron trichloride is an inexpensive, easily accessible, non-flammable gaseous precursor that can be used for a variety of thermal ALE applications. Without being bound by a particular theory, boron trichloride can be used to remove modified layers in a ligand exchange mechanism whereby the exchange of chlorine with fluorine on the modified surface previously modified with a fluorine-containing gas is thermodynamically favorable. Boron trichloride reacts with the fluorinated oxide or chlorinated oxide and causes its constituents to desorb from, and thus be removed from, the wafer. The boron trichloride may also be flowed using a carrier gas such as nitrogen, argon, helium, or neon and/or any inert gas. The removal operation 207 may be stopped by stopping the flow of the boron trichloride to the wafer.

For desorption, a particular temperature range may enable the activation barrier of the modified molecule to be overcome which allows for the release of the modified layer from the wafer. In some examples, the temperature ranges at which chemisorption and desorption occur do not overlap while in others they may partially or fully overlap. Accordingly, in order to remove a molecule from a wafer using chemisorption and desorption, some implementations may maintain the wafer at the same, or substantially same (e.g., within about 10% or 5% of each other), temperature during the removal and modification operations. In order to remove a molecule from a wafer using chemisorption and desorption that occur in different temperature regimes, the operation 203 may occur in the first temperature range and the removal operation 207 may occur in the second different temperature range which may be higher or lower than the first temperature. Some such embodiments may perform multiple cycles to remove multiple layers of material by maintaining the wafer at the same, or substantially the same, temperature during the removal and modification operations, while other embodiments may repeatedly heat and cool the wafer between the two temperature regimes for chemisorption and desorption.

In some of the embodiments that use different temperature regimes, during or before operation 207, the temperature of the wafer may be brought to a second temperature that is different than the first temperature at which the wafer is maintained during the operation 207. In some other embodiments, the second temperature is the same, or substantially the same (e.g., within about 10% or 5% of each other), temperature as the first temperature. This second temperature may be the temperature at which desorption occurs for the one or more modified surface layers. In some embodiments, the second temperature may be greater than the first temperature, and in these embodiments, operation 207 may include heating the wafer from the first temperature to the second temperature. In some other embodiments, the second temperature may be less than the first temperature, and in these embodiments, the wafer may be actively cooled from the first temperature to the second temperature.

The wafer may be heated using radiant heating, convection heating, solid-to-solid heat transfer, or with a plasma. Additionally, the wafer top, bottom, or both, may be heated. The heating of the wafer may also occur in a non-linear fashion, in some embodiments, as discussed further below. As also described below, the wafer may be actively cooled in various manners. In some instances, a wafer may be heated to two different temperatures by positioning the wafer onto two separate wafer supports, such as heated pedestals, that are each maintained at a different temperature than each other. The wafer may therefore be heated to two different temperatures by being transferred between and placed at these two different wafer supports.

In operation 207, the one or more modified surface layers may be removed using boron trichloride in a plasma-less environment. In some embodiments, operation 207 is performed while the wafer is maintained at the second temperature. In some embodiments, the second temperature is the same as the temperature used during operation 203. In some embodiments, the second temperature alone may enable and cause desorption of the modified molecules from the wafer thereby removing the modified molecules from the wafer.

In some embodiments, the second temperature may be about 20° C. to about 500° C., about 20° C. to about 150° C., about 20° C. to about 80° C., about 20° C. to about 100° C., about 100° C. to about 450° C., about 100° C. to about 400° C., about 150° C. to about 400° C., about 200° C. to about 600° C., about 200° C. to about 500° C., about 200° C. to about 350° C., or about 350° C. to about 500° C., or at least about 120° C., or less than about 170° C., for example. Additionally, the wafer may be maintained at the temperature during all, or substantially all (e.g., at least 80%, 90%, or 95%), of the removal operation. The duration of the removal operation may be the duration for which desorption of substantially all (e.g., at least 80%, 90%, or 95%) of desired molecules on the wafer occurs. This may range from about 0.5 seconds to about 600 seconds, about 0.5 seconds to about 400 seconds, about 0.5 seconds to about 300 seconds, about 0.5 seconds to about 10 seconds, about 0.5 seconds to about 5 seconds, about 1 second to about 5 seconds, or about 5 seconds to about 300 seconds, for example.

In some embodiments, operations 203 and 207 are performed isothermally. In some embodiments, operations 203 and 207 are performed isobarically. In some embodiments, operations 203 and 207 are performed isothermally and isobarically. In various embodiments, operations 203-211 are performed without breaking vacuum. In various embodiments, operations 203-211 are performed in the same chamber. In various embodiments, operations 203-211 are performed in the same station of a chamber.

The performance of operation 203 and operation 207 may be considered a single thermal ALE cycle. In some implementations, these operations 203 and 207 may be repeated in order to perform multiple cycles and remove an atomic monolayer, a sub-monolayer, as well as multiple layers of the oxygen-containing material or oxide material. Some embodiments remove a fraction of a monolayer in one cycle as some etch rates may be lower than the lattice constant of the material that is being etched. This may include performing, for example, about 1 to about 1,000 cycles, about 1 to about 500 cycles, about 1 to about 100 cycles, about 1 cycle to about 30 cycles, or about 1 to about 20 cycles. Any suitable number of ALE cycles may be included to etch a desired amount of film. In some embodiments, ALE is performed in cycles to etch about 1 Angstroms (Å) to about 50 Å of the surface of the layers on the wafer. In some embodiments, cycles of ALE etch about 2 Å to about 50 Å of the surface of the layers on the wafer. In some embodiments, each ALE cycle may etch at least about 0.1 Å, 0.5 Å, 1 Å, 2 Å, or 3 Å. As further illustrated in FIG. 2, operations 205 and 207, and in some implementations an optional purge of block 207, may be repeated for N ALE, or etching, cycles. In operation 211, if one determines that the N ALE cycles have been performed, the etching may be finished and thus it may end.

In some operations, an optional purge operation 205 may be performed after the modification operation 203 and before the removal operation 207. In a purge operation, non-surface-bound active modifying molecules, such as the fluorine species or chlorine species, and/or other residue or particulates, may be removed from the process chamber, the chamber walls, the chamber gas volume, and/or the wafer. This can be done by purging and/or evacuating the process chamber to remove the active species or other elements, without removing the adsorbed layer. The species generated in a plasma can be removed by stopping the plasma and allowing the remaining species to decay, optionally combined with purging and/or evacuation of the chamber. Purging can be done using any inert gas such as N₂, Ar, Ne, He and their combinations. Purging may also be done after any operation, block, or step provided herein, including after a modification operation, after a removal operation, or both. Since the purging is optional, some implementations may not have any purging.

Some implementations vary the process conditions of the modifying and removal operations 203 and 207, respectively, such as the duration, temperatures, and pressures of each operation. In some embodiments, operations 203 and 207 may be performed for substantially the same about of time (e.g., within about 10% or 5% of each other), while in other embodiments they may be performed for different times. For example, operation 203 may be performed for a time period shorter or longer than operation 207. The various time periods of each block may range, from about 0.5 seconds to about 600 seconds, about 0.5 seconds to about 400 seconds, about 0.5 seconds to about 300 seconds, about 0.5 seconds to about 10 seconds, about 0.5 seconds to about 5 seconds, about 1 second to about 5 seconds, or about 5 seconds to about 300 seconds, for example.

While operations 201-211 are depicted in FIG. 2, it will be understood that in some embodiments, additional operations and exposures may be used in addition to, between, or before any of operations 201-211.

In one example for etching aluminum oxide, hafnium oxide, or zirconium oxide, an example process flow in accordance with FIG. 2 may involve introducing hydrogen fluoride or nitrogen trifluoride in operation 203, and introducing BCl₃ in operation 207, followed by optionally also introducing a hydrogen plasma.

In another example for etching silicon-doped hafnium oxide, indium gallium zirconium oxide, an oxide alloyed with hafnium and zirconium, or a chalcogenide, an example process flow in accordance with FIG. 2 may involve introducing hydrogen fluoride in operation 203 and introducing BCl₃ in operation 207.

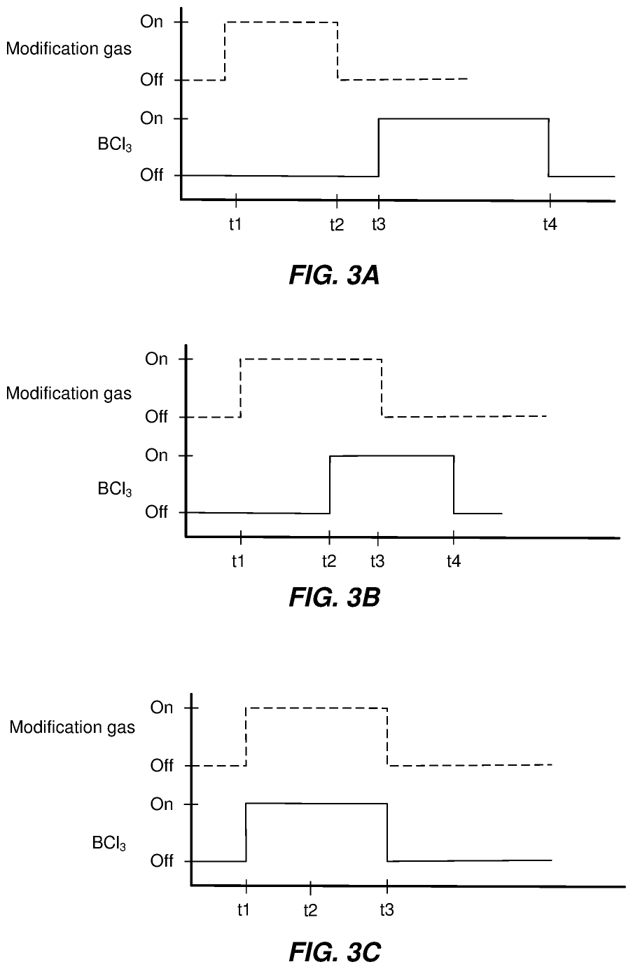

FIGS. 3A through 3C depict example gas flow sequences according to various embodiments. In FIG. 3A, the first process gas with the first species and the second process gas with the second species are flowed onto the wafer without any overlap and may be considered the gas flows described with respect to FIG. 2. Here, the first process gas is flowed from time t1 to time t2 after which it is turned off; this may be considered the modification operation 203. In some instances, the optional purge operation may be performed between time t2 and time t3, such as optional operation 205. At time t3, the second process gas is flowed onto the wafer until time t4 until it is stopped; this time period may be considered the removal operation 207.

In FIG. 3B, the first process gas and the second process gas overlap for only a portion of the etching. At time t1, the first process gas is flowed onto the wafer while the second process gas is not flowed onto the wafer, which proceeds until time t2. This may also be considered the modification operation 203. At time t2, the second process gas is flowed onto the wafer while the first process gas is simultaneously flowed onto the wafer. The first and second process gas both flow onto the wafer between time t2 and time t3; this may be considered the overlapping or co-flowing period of the first and second process gases. At time t3 of FIG. 3B, the first process gas flow is stopped, and the second process gas continues flowing until time t4 when it is stopped. This time may also be considered the removal operation of operation 207.

In some embodiments, the temperature of the wafer may be adjusted during the etching illustrated in FIG. 3B. For example, the wafer may be maintained at a first temperature between times t1 and t2, adjusted to a second temperature at time t2 and maintained at that second temperature until times t3 or t4. In some such implementations, the temperature may be adjusted to a third temperature at time t3 until time t4. In some other embodiments, the temperature may be held at the first temperature from time t1 to time t3 and then adjusted to the second temperature. This may be considered, in some embodiments, temperature ramp up or ramp down sequence with the second temperature greater than or less than the first temperature, and when applicable, the third temperature greater than or less than the second temperature. These temperatures may be any of those provided herein above. Adjusting the temperatures during any of the etching provided herein may allow for additional control and use of chemisorption and desorption. In some other embodiments, the wafer may be maintained at a substantially constant temperature during the etching of FIG. 3B (e.g., within about 10% or 5% of the set temperature).

Similarly, the wafer temperature may be increased or decreased during the modifying, the removing, or both. Referring to FIG. 3A for instance, the wafer temperature may be increased from a first temperature to a greater second temperature, or decreased from a first temperature to a lower third temperature, during the modifying operation between time t1 and time t2. Alternatively or additionally to this, during the removing operation between time t3 and t4, the wafer temperature may also be increased or decreased.

Alternatively or additionally, the chamber pressure may be adjusted during the etching of FIG. 3B. For example, the chamber may be maintained at a first pressure between times t1 and t2, adjusted to a second pressure at time t2 and maintained at that second pressure until times t3 or t4. In some such implementations, the pressure may be adjusted to a third pressure at time t3 until time t4. In some other embodiments, the pressure may be held at the first pressure from time t1 to time t3 and then adjusted to the second pressure. This may be considered, in some embodiments, pressure ramp up or ramp down sequence with the second pressure greater than or less than the first pressure, and when applicable, the third pressure greater than or less than the second pressure. These pressures may be any of those provided herein above. Adjusting the pressure during any of the etching provided herein may allow for additional control and use of chemisorption and desorption, as well as reducing unwanted residue buildup in the chamber. In some other embodiments, the pressure may be substantially constant during the etching of FIG. 3B (e.g., within about 10% or 5% of the set pressure).

Similarly, the chamber pressure increase or decrease may be performed during the modifying, the removing, or both. Referring to FIG. 3A for instance, the chamber pressure may be increased from a first pressure to a greater second pressure, or decreased from a first pressure to a lower second pressure, during the modifying operation between time t1 and time t2. Alternatively or additionally to this, during the removing operation between time t3 and t4, the chamber pressure may also be increased or decreased.

In FIG. 3C, the first species and the second species are co-flowed, or simultaneously flowed, onto the wafer for substantially all of the etching. Due to imperfections in the design, implementation, tolerances, and operation of gas delivery systems, these gases may be intended to be co-flowed for the exactly the same time, but in practice it may not actually be exact. Here in FIG. 3C, the first species and the second species are simultaneously flowed onto the wafer from times t1 to t2 after which they are both stopped. In some implementations, the first and second species may be in the same process gas, along with an optional carrier gas, that is flowed onto the wafer. In some other implementations, the first species may be a part of a first process gas and the second species may be a part of a separate second process gas, as described above, and these first and second process gases are both co-flowed onto the wafer from time t1 to time t2.

In some implementations, it may be advantageous to keep the first and second species separate until they enter the process chamber. This may avoid a cross reaction between the first and second species. The first and second species may therefore be flowed in separate lines and through separate ports into the processing chamber, such as through a dual-plenum showerhead or through separate nozzles, for instance. This may allow the two chemistries to meet only on the wafer surface.

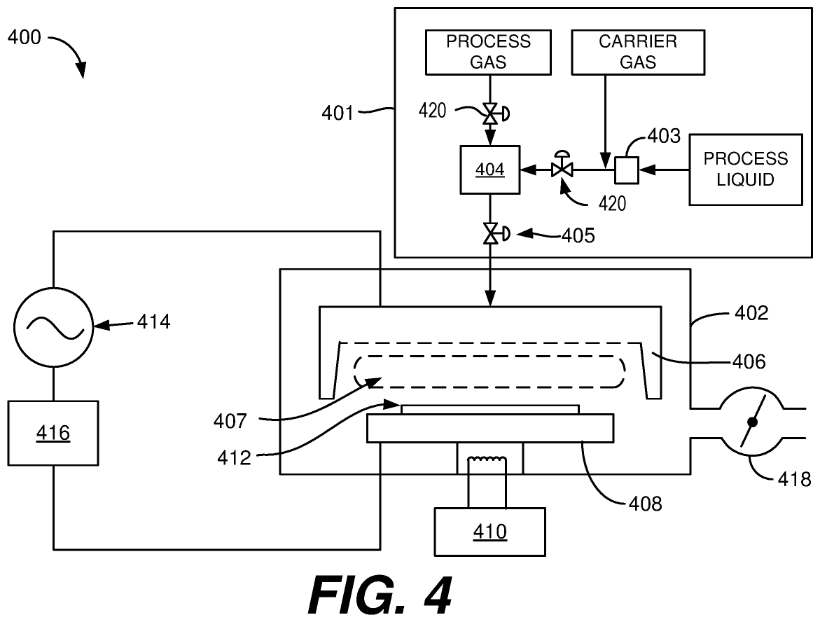

In some embodiments, the temperature of the wafer may be adjusted during the etching illustrated in FIG. 3C and FIG. 4. For example, the wafer may be maintained at a first temperature between times t1 and ta, adjusted to a second temperature at time ta and maintained at that second temperature until time t2. In some such implementations, the temperature may be adjusted to a third temperature or other temperatures throughout this etching. This may be considered, in some embodiments, temperature ramp up or ramp down sequence with, for example, the second temperature greater than or less than the first temperature, and when applicable, the third temperature greater than or less than the second temperature. These temperatures may be any of those provided herein above. In some other embodiments, the wafer may be maintained at a substantially constant temperature during the etching of FIG. 3C.

Alternatively or additionally, the chamber pressure may be adjusted during the etching of FIG. 3C. For example, the chamber may be maintained at a first pressure between times t1 and t2, adjusted to a second pressure at time t2 and maintained at that second pressure until time t3. This may be considered, in some embodiments, pressure ramp up or ramp down sequence with the second pressure greater than or less than the first pressure. These pressures may be any of those provided herein above. In some other embodiments, the pressure may be substantially constant during the etching of FIG. 3C.

### Apparatus

Certain disclosed embodiments herein may be performed on any suitable apparatus, including single-wafer and multi-wafer apparatuses. Certain disclosed embodiments may be performed on a 4-station apparatus. Each station may be configured such as described below. In some embodiments, in a 4-station apparatus, two stations may be configured to perform modification of an atomic layer etching (ALE) process while two stations are configured to perform a thermal removal operation of ALE. For example, two stations may be configured to deliver a fluorine-containing species such as volatilized hydrogen fluoride, and two stations may be configured to deliver boron trichloride in a plasma-less environment. Multi-station apparatuses may be used such that each station or one or more stations are set at different temperatures, which can be used to allow efficient modification and removal. In some embodiments, the apparatus is configured to switch between pressures, or to ramp up and down pressure between operations, or run at the same pressure throughout the process. In some embodiments, modification and removal are performed in the same station. In some embodiments, the station is configured to have modification gases and removal gases to be introduced into the chamber through a showerhead. Further examples are described below with respect to FIGS. 4-9.

FIG. 4 schematically shows an embodiment of a process station 400 that may be used to deposit material using atomic layer deposition (ALD) and/or chemical vapor deposition (CVD), either of which may be plasma enhanced. In various disclosed embodiments, a process station 400 may be used to etch a material by atomic layer etching. For simplicity, the process station 400 is depicted as a standalone process station having a process chamber body 402 for maintaining a low-pressure environment. However, it will be appreciated that a plurality of process stations 400 may be included in a common process tool environment. Further, it will be appreciated that, in some embodiments, one or more hardware parameters of process station 400, including those discussed in detail below, may be adjusted programmatically by one or more computer controllers.

Process station 400 fluidly communicates with reactant delivery system 401 for delivering process gases to a showerhead 406. Reactant delivery system 401 includes a mixing vessel 404 for blending and/or conditioning process gases for delivery to showerhead 406. One or more mixing vessel inlet valves 420 may control introduction of process gases to mixing vessel 404. Similarly, a showerhead inlet valve 405 may control introduction of process gasses to the showerhead 406.

Some reactants may be stored in liquid form prior to vaporization at and subsequent delivery to the process station. For example, hydrogen fluoride may be vaporized. For example, the embodiment of FIG. 4 includes a vaporization point 403 for vaporizing liquid reactant to be supplied to mixing vessel 404. In some embodiments, vaporization point 403 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 403 may be heat traced. In some examples, mixing vessel 404 may also be heat traced. In one non-limiting example, piping downstream of vaporization point 403 has an increasing temperature profile extending from approximately 100° C. to approximately 150° C. at mixing vessel 404.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller upstream of vaporization point 403 may be provided for controlling a mass flow of liquid for vaporization and delivery to process station 400. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 406 distributes process gases toward substrate 412. Example process gases include but are not limited to hydrogen fluoride, nitrogen trifluoride, and boron trichloride. In the embodiment shown in FIG. 4, substrate 412 is located beneath showerhead 406, and is shown resting on a pedestal 408. The pedestal may be an electrostatic chuck. The pedestal may be heated to a temperature of about 150° C. to about 500°, or about 200° C. to about 400° C. It will be appreciated that showerhead 406 may have any suitable shape, and may have any suitable number and arrangement of ports for distributing processes gases to substrate 412.

In some embodiments, a microvolume 407 is located beneath showerhead 406. Performing processes in a microvolume rather than in the entire volume of a process station may reduce reactant exposure and purge times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 408 may be raised or lowered to expose substrate 412 to microvolume 407 and/or to vary a volume of microvolume 407. For example, in a substrate transfer phase, pedestal 408 may be lowered to allow substrate 412 to be loaded onto pedestal 408. During a deposition process phase, pedestal 408 may be raised to position substrate 412 within microvolume 407. In some embodiments, microvolume 407 may completely enclose substrate 412 as well as a portion of pedestal 408 to create a region of high flow impedance during a deposition process.

Optionally, pedestal 408 may be lowered and/or raised during portions the deposition process to modulate process pressure, reactant concentration, etc., within microvolume 407. In one scenario where process chamber body 402 remains at a base pressure during the deposition process, lowering pedestal 408 may allow microvolume 407 to be evacuated. Example ratios of microvolume to process chamber volume include, but are not limited to, volume ratios between 1:2000 and 1:10. It will be appreciated that, in some embodiments, pedestal height may be adjusted programmatically by a suitable computer controller.

In another scenario, adjusting a height of pedestal 408 may allow a plasma density to be varied during plasma operations in a modification operation of a thermal ALE process. At the conclusion of a process phase, pedestal 408 may be lowered during another substrate transfer phase to allow removal of substrate 412 from pedestal 408.

While the example microvolume variations described herein refer to a height-adjustable pedestal, it will be appreciated that, in some embodiments, a position of showerhead 406 may be adjusted relative to pedestal 408 to vary a volume of microvolume 407. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers.

In some embodiments, the processing chamber in FIG. 400 does not use a plasma for the thermal ALE and therefore does not have plasma-related equipment. In some other embodiments, a plasma may be used or the reactor may have such plasma-related equipment. For example, as shown in FIG. 4, showerhead 406 and pedestal 408 electrically communicate with RF power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 50 kHz and 2000 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

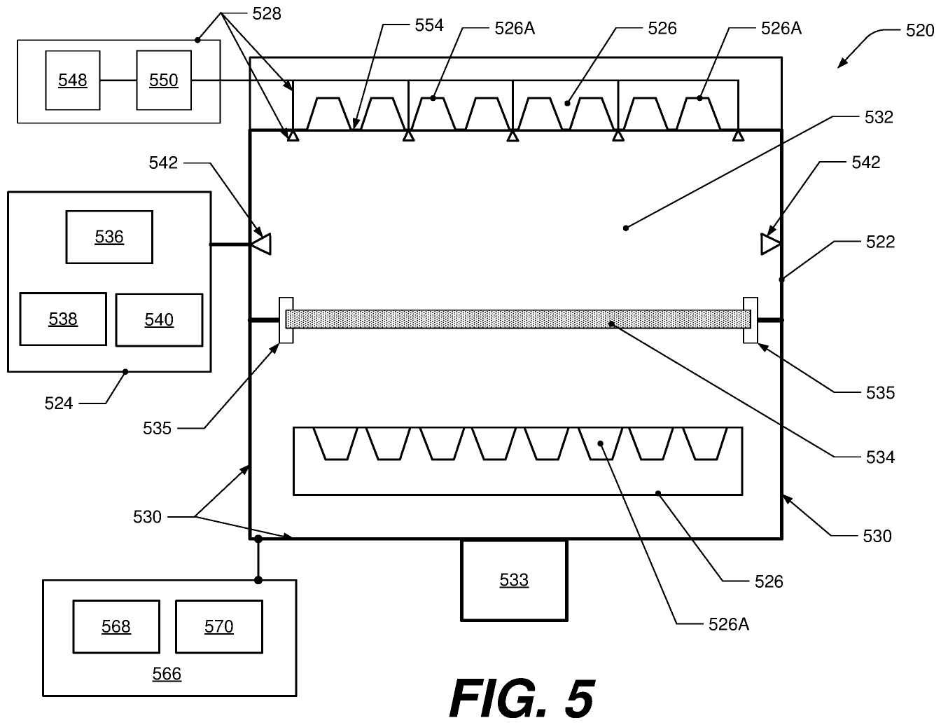

In some embodiments, pedestal 408 may be temperature controlled via heater 410. In some embodiments, the heater 410 may be the same as the heater unit described above and shown in FIGS. 5-7, such as a heater unit that includes a plurality of LEDs used to heat the wafer. Further, in some embodiments, pressure control for process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to process station 400.

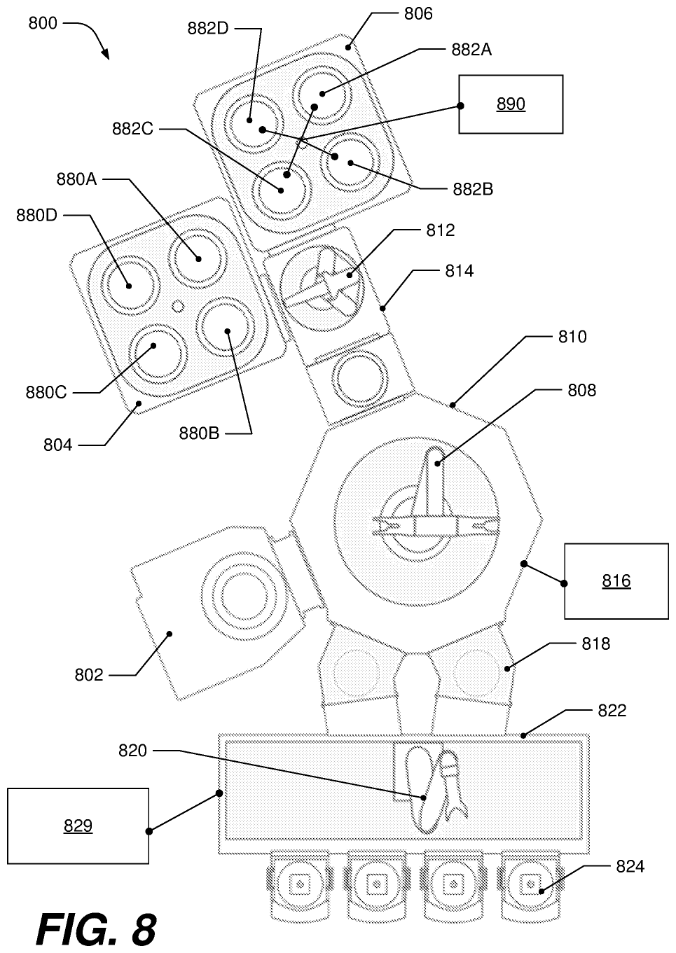

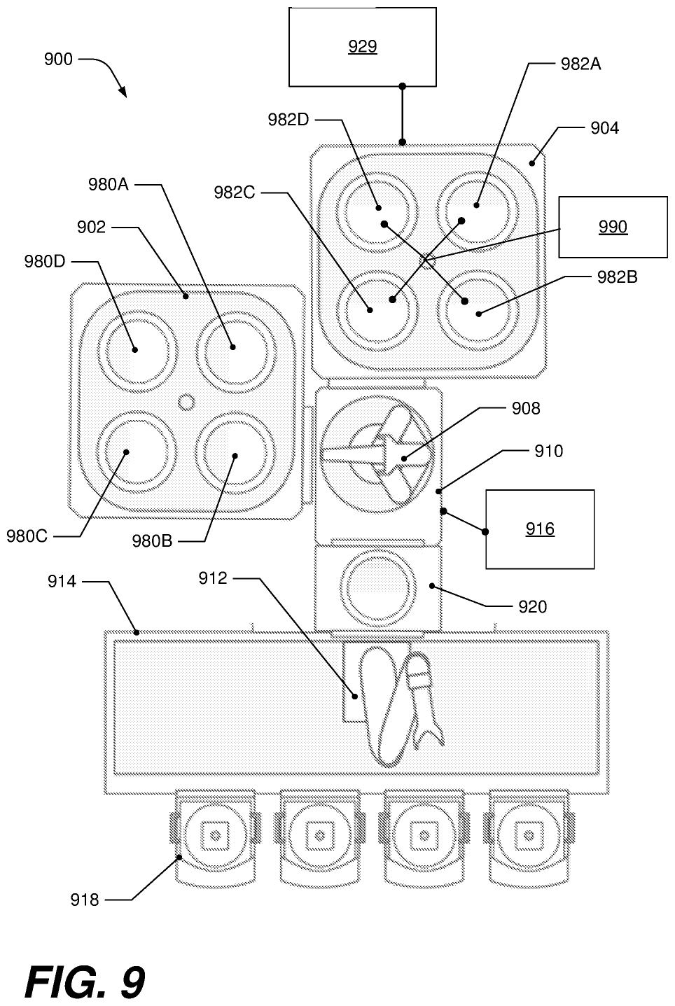

Although FIG. 4 is depicted as a single station, it will be appreciated that a processing chamber may have multiple such stations that share gas delivery systems or other equipment. For example, as shown in FIGS. 8 and 9, chambers 804, 806, 902, and 904 include four processing stations. Each station may include any and all of the features described with respect to the single stations in FIG. 4-7. The stations in chambers 804 and 902 may be used for etching and the stations in chambers 806 and 904 may be used for depositing material on the wafer. For instance, each station of chambers 804 and 902 may be used to perform thermal etching, such as thermal ALE, on a wafer held in a wafer holder, such as a pedestal, at a particular process station; similarly each station of chambers 806 and 904 may be used to perform deposition, such as ALD and thermal ALD, on a wafer held in a wafer holder at a particular process station. Other similar multi-station processing apparatuses may have more or fewer process stations depending on the implementation and, for example, a desired level of parallel wafer processing, size/space constraints, cost constraints, etc.

For some processing chambers, such as deposition chambers 806 and 904 in FIGS. 8 and 9, respectively, an RF subsystem 890 and 990 may generate and convey RF power to integrated circuit fabrication chamber 806 and 904 via radio frequency input ports. In particular embodiments, integrated circuit fabrication chambers 806 and 904 may comprise input ports in addition to radio frequency input ports. Accordingly, integrated circuit fabrication chambers 806 and 904 may utilize 8 RF input ports. In particular embodiments, stations 882A-D and 982A-D of integrated circuit fabrication chambers 806 and 904 may each utilize first and second input ports in which a first input port may convey a signal having a first frequency and in which a second input port may convey a signal having a second frequency. In some embodiments, stations such as stations 882A-D and 982A-D may utilize more than two input ports; each input port may convey a signal having different frequencies. In some embodiments, multiple RF generators may be used. Use of dual frequencies may bring about enhanced plasma characteristics. In various embodiments, multiple electrodes may be in the substrate support. In some embodiments, additional electrodes may be in the edge rings.

As provided above, a system controller may be employed on the tools described herein to control process conditions during etching and/or deposition. The controller, 829 in FIG. 8, and 929 in FIG. 9, for example, will typically include one or more memory devices and one or more processors. The controller 829 may control all of the activities of the tool 800 and/or 900. In some implementations, the controller 829 and/or 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The controller is configured to perform any technique described above. For instance, referring to tool 800 of FIG. 8 or tool 900 of FIG. 9, and technique of FIG. 2, in some embodiments the controller 829 and/or 929 is configured to cause the substrate heating unit to bring (i.e., heat) the wafer positioned on the substrate support features to a first temperature, and cause the process gas unit to flow the first process gas to the wafer. As noted above, the first process gas is configured to modify one or more surface layers of the material on the wafer by chemical adsorption, without using a plasma in some embodiments, while the wafer is maintained at the first temperature. The controller may further be configured to cause the process gas unit to flow the second process gas or boron trichloride onto the substrate as described herein to remove the modified layer of material. The controller is further configured to cause the wafer transfer unit, including any of the robotic arms, to transport the wafer between any of the processing stations and to control the pressure units 816 and 916, which may include one or more vacuum pumps, to control the pressure within the tool and the chambers.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

The present disclosure includes the apparatuses provided above and herein below. Referring now to FIG. 5, an example of a substrate processing chamber for etching materials according to the present disclosure is shown. While a specific substrate processing chamber is shown and described, the methods described herein may be implemented on other types of substrate processing systems. In various embodiments, a suitable apparatus or chamber for processing certain disclosed embodiments include one or more of the following components: an anodized chamber body, an anodized top plate, an anodized liner, ceramic or anodized aluminum pedestal, delivery lines capable of being heated to deliver boron trichloride, stainless steel low pressure components having high nickel content, and yttria coating.

FIG. 5 depicts an example apparatus 520 for semiconductor processing in accordance with disclosed embodiments, including thermal atomic layer etching; this apparatus 520 includes a chamber 522, a process gas unit 524, a substrate heating unit 526, and a substrate cooling unit 528. The processing chamber 522 has chamber walls 530 that at least partially bound and define a chamber interior 532 (which may be considered a plenum volume).

The process gas unit 524 is configured to flow process gases, which may include liquids and/or gases, such as a reactant, modifying molecules, converting molecules, or removal molecules, onto a substrate 534 in the chamber interior 532. The process gas unit 524 also includes one or more flow features 542 configured to flow the first process gas onto the substrate 534, such as a hole, a nozzle (two of which are depicted), or a showerhead. The one or more flow features 542 may be positioned above, below, on the side, or a combination of positions, within the chamber interior 532, such as on the processing chamber walls, top, and bottom, for instance. The process gas unit 524 may include a mixing vessel for blending and/or conditioning process gases for delivery to the chamber interior 532. One or more mixing vessel inlet valves may control introduction of process gases to the mixing vessel.

The process gas unit 524 may include a first process gas source 536, a first process liquid source 538, a vaporization point (not depicted) which may vaporize the first liquid into a gas, and a carrier gas source 540. Some reactants may be stored in liquid form prior to vaporization and subsequent to delivery to the chamber 522. The first process gas may comprise a chlorine or a fluorine configured to modify one or more layers of material on the substrate, without using a plasma, in some embodiments; the second process gas may comprise a compound having boron and chlorine, such as boron trichloride, onto the wafer in the second processing chamber as described above.

In some implementations, the vaporization point may be a heated liquid injection module. In some other implementations, the vaporization point may be a heated vaporizer. In some other embodiments, the vapor may be generated by drawing a vacuum above a container containing the liquid reagent. In yet other implementations, the vaporization point may be eliminated from the process station. In some implementations, a liquid flow controller (LFC) upstream of the vaporization point may be provided for controlling a mass flow of liquid for vaporization and delivery to the chamber interior 532. The carrier gas source 540 includes one or more carrier gases or liquids that may be flowed with the processing gas; these may be inert gases like N₂, Ar, Ne, He. The apparatus 520 may also include a vacuum pump 533 configured to pump the chamber interior to low pressures, such as a vacuum having a pressure of 1 mTorr or 10 Torr, for example. The chamber interior 532 includes substrate support features 535 that are configured to support and thermally float a substrate 534 in the chamber. The substrate support features 535 may include clamps, horizontal pins or supports, vertical pins or supports, and semi-circular rings, for instance, that support the substrate 534 in the chamber interior 532. These features are configured to support the substrate 534 such that the thermal mass of the substrate 534 is reduced as much as possible to the thermal mass of just the substrate. Each substrate support feature 535 may therefore have minimal contact with the substrate 534 and may be the smallest number of features required to adequately support the substrate during processing (e.g., in order to support the weight of the substrate and prevent inelastic deformation of the substrate). For instance, the surface area of one substrate support feature 535 in contact with a substrate may be less than about 1%, 0.5%, 0.1%, 0.05%, or 0.01% of the overall surface area of the back side of the substrate; also, for instance, 2, 3, or 4 features may be utilized.

In one example, the substrate support features 535 may include two or more vertical pins that have grooves wrapped or spiraled along the vertical, longitudinal axis and that are offset at varying distances from the longitudinal axis and configured to support a substrate. When the vertical pin rotates along its longitudinal axis and the edge of a substrate is positioned in the groove, the edge of the groove, and therefore the edge of the substrate, moves farther away from the longitudinal axis. When multiple vertical pins are used to support a substrate, the rotation of the vertical pins causes the grooves to apply a supporting force to the substrate in a direction perpendicular to the longitudinal axis.

In some embodiments, the chamber 522 may include a wafer support pedestal that includes substrate lift pins. In some embodiments, the wafer support pedestal is made of ceramic. During thermal ALE processing, the lift pins may support and position the substrate away from the pedestal such that there is substantially no transference of thermal energy between the pedestal and substrate (e.g., less than 10%, 5%, 1%, 0.5%, or 0.1% of energy transferred between the two). In some other embodiments, the chamber 522 may not have a pedestal. In some embodiments, an electrostatic chuck (ESC) may be used that contains substrate heating unit 526 configured to heat the substrate to temperatures provided herein, such as between about 20° C. and 500° C.

The substrate heating unit 526 is configured to heat the substrate to multiple temperatures and maintain such temperatures for at least 1 second, 5 seconds, 10 seconds, 30 seconds, 1 minute, 2 minutes, or 3 minutes, for example. In some embodiments, the substrate heating unit 526 is configured to heat the substrate between at least two temperature ranges, with the first range between about 20° C. and 150° C., and the second range between about 200° C. and 600° C., as well as configured to maintain the substrate at a temperature within these ranges for at least 1 second, 5 seconds, or 10 seconds, for example. Additionally, in some embodiments, the substrate heating unit 526 is configured to heat the substrate from the first temperature range to the second temperature range in less than about 250 milliseconds, 150 milliseconds, 100 milliseconds, or 50 milliseconds, for instance.

In some embodiments, the substrate heating unit 526 is made of ceramic. The substrate heating unit 526 may utilize radiant heating, convective heating, laser heating, plasma heating, solid-to-solid thermal transference (e.g., transferring heat generated by one or more heating elements in a heated electrostatic chuck or pedestal to a substrate supported by or on that chuck or pedestal), or a combination of these items. For radiant heating, the substrate heating unit 526 may be used for emitted light heating, ultraviolet heating, microwave heating, radio frequency heating, and induction heating. For example, the substrate heating unit 526 may include light emitting diodes (LEDs) that emit visible light with wavelengths that may include and range between 400 nanometers (nm) and 800 nm. This may also include, for instance, a heat lamp, light emitting diodes (e.g., LEDs), a ceramic heater, a quartz heater, or a plurality of Gradient Index (GRIN) Lenses connected to a light energy source. A GRIN lens is configured to deliver heat energy (thermal or light) from the light energy source to the substrate in a uniform manner; the light source may be a laser or high-intensity light source that transmits the heat energy through a conduit, such as a fiber optic cable, to the GRIN lenses. The heating elements utilized by the substrate heating unit 526 may be positioned above, below, on the side, or a combination of the positions, the substrate 534, and they may be positioned inside, outside, or both, the chamber interior 532. In FIG. 5, the heating elements utilized by the substrate heating unit 526 include a plurality of LEDs 526A that are positioned both above and below the substrate 534; the lower heating elements are positioned inside the chamber interior 532 and the upper heating elements are positioned outside the chamber interior 532. In some embodiments, for some of the heating elements that are positioned outside the chamber 522 (which may also be referred to as a “process chamber”), the chamber 522 may have a window 554 that allows for the radiation to be transmitted into the chamber interior 532 and onto the substrate 534. In some embodiments, this window 554 may be an optical-grade quartz plate while in other embodiments it may be a transparent indium tin oxide (ITO) window. In some embodiments, the substrate heating unit 526 include a plurality of LEDs 526A may only be positioned underneath the substrate 534, which may include inside a pedestal or ESC that also may include a window through which the light emitted by the LEDs may reach the backside of the substrate. In various embodiments, low pressure components downstream of the MFC are made of stainless steel with high nickel content made out of Hastelloy.

For solid-to-solid thermal transference, the substrate heating unit 526 may have one or more heating surfaces that are configured to contact and heat the substrate in the chamber interior. In some embodiments, the substrate heating unit 526 may have a heating platen, such as a flat surface or a surface of a substrate pedestal, that is configured to contact the back surface of the substrate and heat the substrate. This heating platen may have heating elements such as a heating coil, heating fluid, or radiative heating discussed above, that may heat the surface of the heating platen. The substrate may be heated when the back of the substrate is in direct contact with, or is offset from the heating platen but close enough to receive thermal energy from, the heating platen. When using this solid-to-solid thermal transference to heat the substrate, the substrate is separated from the heating platen when it is cooled. While some conventional ALE apparatuses may have a substrate pedestal that includes both heating and cooling elements, these apparatuses are unable to quickly (e.g., under 250 milliseconds) cycle between the temperatures of thermal ALE because of the large thermal masses of the pedestal that are repeatedly heated and cooled. For instance, it may take multiple seconds or minutes to heat a pedestal from a first temperature range (e.g., 20° C. to 100° C.) to a second temperature range (e.g., 200° C. to 500° C.), as well as to cool the pedestal from the second temperature range to a lower temperature that can cool the substrate to the first temperature range. Accordingly, after using this solid-to-solid heating technique, the heating platen and the substrate are separated from each other which may be accomplished, for instance, by moving the substrate and/or the heating platen away from each other. Without this separation, cooling occurs of both the thermal mass of the substrate and the heating platen which increases the cooling time which decreases substrate throughput. In some embodiments, an ESC or pedestal having the substrate heating unit and a Peltier element for cooling may enable fast heating and cooling times (such as about 30 seconds to cool a substrate to a desired temperature). In some embodiments, this may be performed at low pressures, such as less then 1 Torr, including less than 50 mTorr, for example.

The substrate cooling unit 528 of FIG. 5 is configured to actively cool the substrate. In some embodiments, the substrate cooling unit 528 flows a cooling gas onto the substrate 534 which actively cools the substrate 534. The substrate cooling unit 528 may include a cooling fluid source 548 which may contain a cooling fluid (a gas or a liquid), and a cooler 550 configured to cool the cooling fluid to a desired temperature, such as less than or equal to 0° C., −50° C., −100° C., −150° C., −170° C., −200° C., and −250° C., for instance. The substrate cooling unit 528 includes piping and coolant flow features (not shown), e.g., nozzles or holes, that are configured to flow the coolant fluid into the chamber interior 532. In some embodiments, the fluid may be in liquid state when it is flowed to the chamber 522 and may turn to a vapor state when it reaches the chamber interior 532, for example if the chamber interior 532 is at a low pressure state, such as 1 Torr, for instance. The cooling fluid may be an inert element, such as nitrogen, argon, helium. In some embodiments, the flow rate of the cooling fluid into the chamber interior 532 may be at least 10 liters per second, 50 liters per second, 100 liters per second, 150 liters per second, 200 liters per second, 250 liters per second, and 300 liters per second, for example.

Various factors may increase the ability of the cooling fluid to cool the substrate. It has been discovered through various experiments that the higher the flow rate of the cooling fluid, the faster the substrate is cooled. In one example experiment, a cooling gas at about −196° C. flowed onto a substrate at a flow rate of 1 liter per second was found to reduce the temperature of a substrate from about 220° C. to about 215° C. in about 5,000 milliseconds, while the same cooling gas a flow rate of 10 liters per second reduced the temperature of a substrate from about 220° C. to about 195° C. in about 5,000 milliseconds. It was also discovered that a gap between the substrate and the top of the chamber may also affect the cooling of the substrate; the smaller the gap, the higher the cooling. In one instance, it was discovered that a substrate separated from the top of the chamber by a gap of about 50 micrometers was cooled from about 220° C. to about 215° C. in about 5,000 milliseconds using a cooling gas at about −196° C., while a substrate separated from the top of the chamber by a gap of about 5 millimeters was cooled from about 220° C. to about 209° C. in about 5,000 milliseconds using the same cooling gas. Accordingly, it was discovered that the higher the flow rate and the smaller the gap, the faster the substrate is cooled.

In some embodiments, the substrate cooling unit 528 may use solid-to-solid thermal transference to actively cool the substrate 534. In some of these embodiments, a cooling platen, such as a flat, cooled surface may be used to contact the bottom of the substrate and cool the substrate. This platen may be cooled by flowing a cooling fluid on, through, or underneath the platen. When using this solid-to-solid cooling, similar to the solid-to-solid heating discussed above, the substrate is separated from the cooling platen during heating of the substrate, such as by moving the substrate away from the cooling platen by, for instance, raising it up with lift pins. Without this separation, both the thermal masses of the substrate and cooling platen are cooled which requires more cooling that in turn increases process time and decreases throughput. In some embodiments, radiant heating of the top of the substrate or plasma heating of the bottom of the substrate may be used in conjunction with solid-to-solid cooling.

In some embodiments, the substrate cooling unit 528 may use laser cooling to cool the substrate. This may enable the cooling of a substrate that includes thulium molecules on at least the exposed surface of the substrate by utilizing a reverse Navier-Stokes reaction. For example, the temperature of the substrate manifests itself in phonons and the laser cooling emits photons to the substrate surface which interact with and pick-up phonons in the thulium, and then leave the substrate with the phonon from the thulium at a higher energy level. The removal of these phonons causes a decrease in the temperature of the substrate. The thulium may be doped onto the surface of the substrate in order to enable this laser cooling, and this doping may be incorporated into the techniques listed above, such as occurring after or before any operation, such as the removal operation.

As noted above, some embodiments of the apparatus may include a plasma source configured to generate a plasma within the chamber interior. These plasma sources may be a capacitively coupled plasma (CCP), an inductively coupled plasma (ICP), an upper remote plasma, and a lower remote plasma.

In some embodiments, the apparatuses described herein may include a controller that is configured to control various aspects of the apparatus in order to perform the techniques described herein. For example, in FIG. 5, apparatus 520 includes a controller 566 (which may include one or more physical or logical controllers) that is communicatively connected with and that controls some or all of the operations of a processing chamber. The controller 566 may include one or more memory devices 568 and one or more processors 570. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 550 ms. Switching time may depend on the flow chemistry, recipe chosen, reactor architecture, and other factors.

In some implementations, the controller 566 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 566, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 566 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 566, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 566 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 566 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 566 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. For instance, referring to apparatus 520 of FIG. 5 and technique of FIG. 2, in some embodiments the controller 566 is configured to cause the substrate heating unit 526 to bring (i.e., heat) the substrate 534 positioned on the substrate support features 535 to a first temperature, and cause the process gas unit 524 to flow the first process gas to the substrate 534. As noted above, the first process gas is configured to modify one or more surface layers of the material on the substrate 534 by chemical adsorption, without using a plasma in some embodiments, while the substrate is maintained at the first temperature. The controller 566 may further be configured to cause the process gas unit to flow the second process gas onto the substrate 534 as described herein to remove the modified layer of material. Some implementations include the controller 566 causing one or more layers of encapsulation material to be deposited onto the substrate 534 as provided herein.

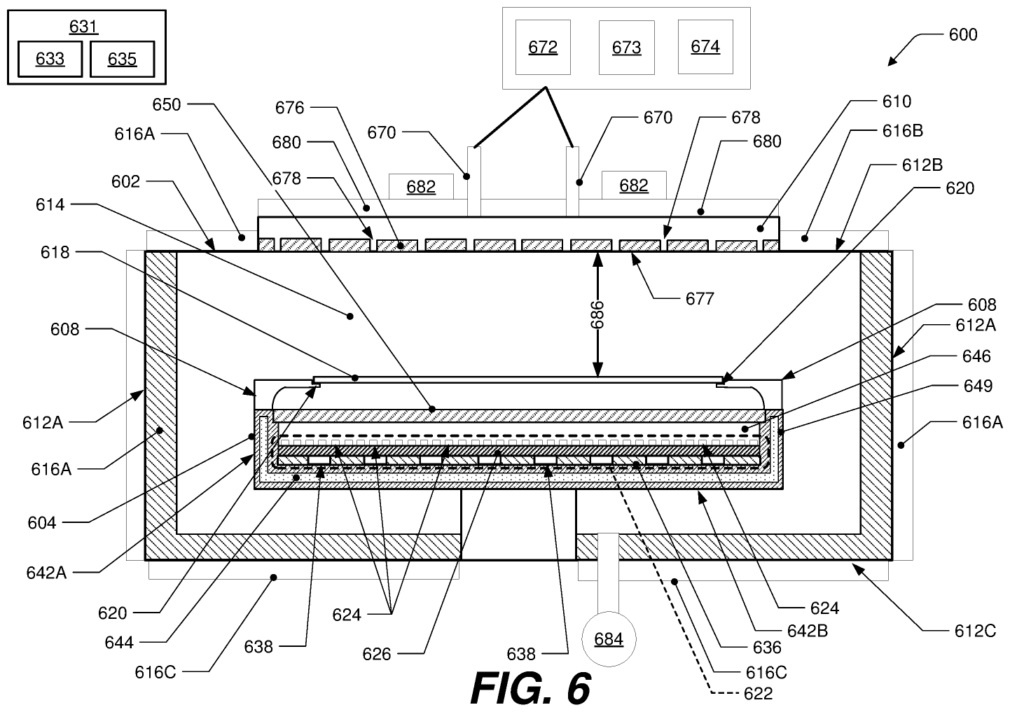

As noted above, some etching performed herein may temperature controlled features of the processing chamber, such as its side walls, top, and/or bottom, as well as the showerhead and gas delivery system. FIG. 6 depicts a cross-sectional side view of an example apparatus in accordance with disclosed embodiments. As detailed below, this apparatus 600 is capable of rapidly and precisely controlling the temperature of a substrate, including performing thermal etching operations. The apparatus 600 includes a processing chamber 602, a pedestal 604 having a substrate heater (not shown) and a plurality of substrates supports 608 configured to support a substrate 618, and a gas distribution unit 610.

The processing chamber 602 includes sides walls 612A, a top 612B, and a bottom 612C, that at least partially define the chamber interior 614, which may be considered a plenum volume. As stated herein, it may be desirable in some embodiments to actively control the temperature of the chamber walls 612A, top 612B, and bottom 612C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 612A, the top 612B, and the bottom 612C. As illustrated in FIG. 6, chamber heaters 616A are positioned on and configured to heat the chamber walls 612A, chamber heaters 616B are positioned on and configured to heat the top 612B, and chamber heaters 616C are positioned on and configured to heat the bottom 612C. The chamber heaters 616A-616C may be resistive heaters that are configured to generate heat when an electrical current is flowed through a resistive element. Chamber heaters 616A-616C may also be fluid conduits through which a heat transfer fluid may be flowed, such as a heating fluid which may include heated water. In some instances, the chamber heaters 616A-616C may be a combination of both heating fluid and resistive heaters. The chamber heaters 616A-616C are configured to generate heat in order to cause the interior surfaces of each of the chamber walls 612A, the top 612B, and the bottom 612C to the desired temperature, which may range between about 40° C. and about 150° C., including between about 80° C. and about 130° C., about 90° C. or about 120° C., for instance. It has been discovered that under some conditions, water and alcohol vapors do not condense on surfaces kept at about 90° C. or higher.

The chamber walls 612A, top 612B, and bottom 612C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. In some embodiments, the chamber includes an anodized aluminum liner. These materials are configured to withstand the chemistries used in the processing techniques, such as anhydrous HF, water vapor, methanol, isopropyl alcohol, chlorine, fluorine gases, nitrogen gas, hydrogen gas, helium gas, and the mixtures thereof.

The apparatus 600 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 684 configured to pump the chamber interior 614 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 604 will now be discussed. The pedestal 604 includes a substrate heater 622 (encompassed by the dashed rectangle in FIG. 6) that has a plurality of LEDs 624 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon wafers from ambient temperature, e.g., about 20° C., to about 600° C. because silicon absorbs light within this range. In contrast, radiant, including infrared radiant, heating may ineffectively heat silicon at temperatures up to about 400° C. because silicon tends to be transparent to infrared at temperatures lower than about 400° C. Traditional “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat a traditional pedestal to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip is typically limited to having three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

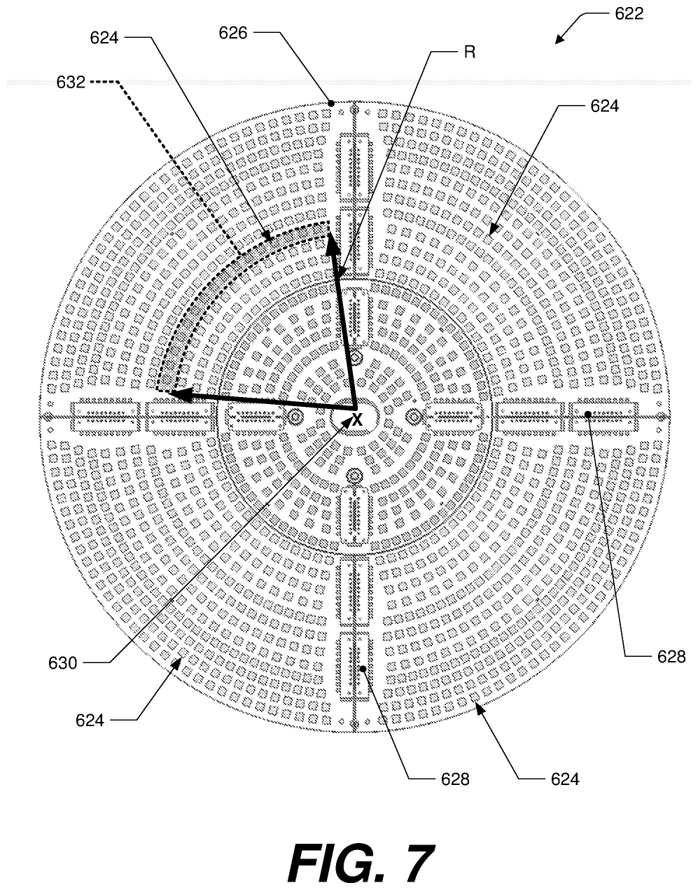

FIG. 7 depicts a top view of a substrate heater with a plurality LEDs. This substrate heater 622 includes a printed circuit board (PCB) 626 and the plurality of LEDs 624, some of which are labeled; this depicted plurality includes approximately 1,300 LEDs. External connections 628 are connected by traces to provide power to the plurality of LEDs 624. As illustrated in FIG. 7, the LEDs may be arranged along numerous arcs that are radially offset from the center 630 of the substrate heater 622 by different radiuses; in each arc, the LEDs may be equally spaced from each other. For example, one arc 632 is surrounded by a partially shaded dotted shape, includes 16 LEDs 624, and is a part of a circle with a radius R that extends around the center 630. The 16 LEDs 624 may be considered equally spaced from each other along this arc 632.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses 4 watts or less at 100% power, including 3 watts at 100% power and 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85, 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (i.e., an annular sector), an arc, a segment, and a sector that may be centered on the center of the heater and have a radius less than or equal to the overall radius of the substrate heater's PCB. These zones are able to adjust the temperature at numerous locations across the wafer in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 622 is configured to heat the substrate to multiple temperatures and maintain each such temperatures for various durations. These durations may include the following non-limiting examples of at least about 1 second, at least about 5 seconds, at least about 10 seconds, at least about 30 seconds, at least about 60 seconds, at least about 90 seconds, at least about 120 second, at least about 150 seconds, or at least about 180 seconds. The substrate heater may be configured to heat the substrate to between about 50° C. and 600° C., including between about 50° C. and 150° C., including about 130° C., or between about 150° C. and 350° C., for example. The substrate heater may be configured to maintain the substrate at a temperature within these ranges for various durations, including the following non-limiting examples: at least about 1 second, at least about 5 seconds, at least about 10 seconds, at least about 30 seconds, at least about 60 seconds, at least about 90 seconds, at least about 120 seconds, at least about 150 seconds, or at least about 180 seconds, for example. Additionally, in some embodiments, the substrate heater 622 is configured to heat the substrate to any temperature within these ranges in less than about 60 seconds, less than about 45 seconds, less than about 30 seconds, or less than about 15 seconds, for instance. In certain embodiments, the substrate heater 622 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit between about 10 W and 4000 W, including at least about 10 W, at least about 30 W, at least about 0.3 kilowatt (kW), at least about 0.5 kW, at least about 2 kW, at least about 3 kW, or at least about 4 kW. The apparatus is configured to supply between about 0.1 kw and 9 kW of power to the pedestal; the power supply is connected to the substrate heater through the pedestal but is not depicted in the Figures. During temperature ramps, the substrate heater may operate at the high powers, and may operate at the lower power levels (e.g., include between about 5 W and about 0.5 kW) to maintain the temperature of a heated substrate.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 6, the substrate heater includes a pedestal cooler 636 in direct contact with the bottom of the PCB 626. Heat is configured to flow from the LEDs, to the PCB 626, and to the pedestal cooler 636. The pedestal cooler 636 also includes a plurality of fluid conduits 638 through which a heat transfer fluid, such as water, is configured to flow in order to receive the heat and thus cool the LEDs in the substrate heater 622. The fluid conduits 638 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 602. In some instances, it may similarly be advantageous to heat the exterior surfaces of the pedestal 604 in order to prevent unwanted condensation and deposition on its external surfaces. As illustrated in FIG. 6, the pedestal 604 may further include a pedestal heater 644 inside of the pedestal 604 that is configured to heat the exterior surfaces of the pedestal 604, including its sides 642A and bottom 642B. The pedestal heater 644 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 6, the window 650 may be positioned above the substrate heater 622 and may be sealed to the sidewall 649 of the pedestal 604 in order to create a plenum volume within the pedestal that is fluidically isolated from the chamber interior. This plenum volume may also be considered the inside of the bowl 646. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any holes or openings within it. In some embodiments, the heater may have a thickness of 15 to 30 mm, including 20 mm and 25 mm.

As shown in FIG. 6, the pedestal's 604 substrate supports 608 are configured to support the substrate 618 above and offset from the window 650 and the substrate heater 622. In certain embodiments, the temperature of the substrate can be rapidly and precisely controlled by thermally floating, or thermally isolating, the substrate within the chamber. The heating and cooling of a substrate is directed at both the substrate's thermal mass and the thermal masses of other items in contact with the substrate. For instance, if the substrate is in thermal contact with a large body, such as the entirety of the substrate's back side resting on a large surface of a pedestal or electrostatic chuck as in many conventional etching apparatuses, this body acts as a heat sink for the substrate which affects the ability to accurately control the substrate temperature and reduces the quickness of substrate heating and cooling. It is therefore desirable to position the substrate so that the smallest thermal mass is heated and cooled. This thermal floating is configured to position the substrate so that it has minimal thermal contact (which includes direct and radiation) with other bodies in the chamber.

The pedestal 604 is therefore configured, in some embodiments, to support the substrate 618 by thermally floating, or thermally isolating, the substrate within the chamber interior 614. The pedestal's 604 plurality of substrate supports 608 are configured to support the substrate 618 such that the thermal mass of the substrate 618 is reduced as much as possible to the thermal mass of just the substrate 618. Each substrate support 608 may have a substrate support surface 620 that provides minimal contact with the substrate 618. The number of substrate supports 608 may range from at least 3 to, for example, at least 6 or more. The surface area of the support surfaces 620 may also be the minimum area required to adequately support the substrate during processing operations (e.g., in order to support the weight of the substrate and prevent inelastic deformation of the substrate). In some embodiments, the surface area of one support surface 620 may be less than about 0.1%, less than about 0.075%, less than about 0.05%, less than about 0.025%, or less than about 0.01%, for instance.

The substrate supports are also configured to prevent the substrate from being in contact with other elements of the pedestal, including the pedestal's surfaces and features underneath the substrate. The substrate 618 is also offset from the substrate heater 622 (as measured in some instances from a top surface of the substrate heater 622 which may be the top surface of the LEDs 624) by a distance which may affect numerous aspects of heating the substrate 618.

As stated, the substrate supports 608 are configured to support the substrate 618 above the window. In some embodiments, these substrate supports are stationary and fixed in position; they may not be lift pins or a support ring. In some embodiments, at least a part of each substrate support 608 that includes the support surface 620 may be comprised of a material that is transparent at least to light emitted by LEDs 624. This material may be, in some instances, quartz or sapphire. The transparency of these substrate supports 608 may enable the visible light emitted by the substrate heater's 622 LEDs to pass through the substrate support 608 and to the substrate 618 so that the substrate support 608 does not block this light and the substrate 618 can be heated in the areas where it is supported. This may provide a more uniform heating of the substrate 618 than with a substrate support comprising a material opaque to visible light. In some other embodiments, the substrate supports 608 may be comprised of a non-transparent material, such as zirconium dioxide (ZrO₂).

Referring back to FIG. 6, in some embodiments, the pedestal is also configured to move vertically. This may include moving the pedestal such that a gap 686 between a faceplate 676 of the gas distribution unit 610 and the substrate 618 is capable of being in a range of 2 mm and 70 mm. As provided in more detail below, moving the pedestal vertically may enable active cooling of the substrate as well as rapid cycling time of processing operations, including flowing gas and purging, due to a low volume created between the gas distribution unit 610 and the substrate 618. This movement may also enable the creation of a small process volume between the substrate and the gas distribution unit which can result in a smaller purge and process volume and thus reduce purge and gas movement times and increase throughput.

The gas distribution unit 610 is configured to flow process gases, which may include liquids and/or gases, such as a reactant, modifying molecules, converting molecules, or removal molecules, onto the substrate 618 in the chamber interior 614. As seen in FIG. 6, the gas distribution unit 610 includes one or more fluid inlets 670 that are fluidically connected to one or more gas sources 672 and/or one or more vapor sources 674. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 610 also includes the faceplate 676 that includes a plurality of through-holes 678 that fluidically connect the gas distribution unit 610 with the chamber interior 614. These through-holes 678 are fluidically connected to the one or more fluid inlets 670 and also extend through a front surface 677 of the faceplate 676, with the front surface 677 configured to face the substrate 618. In some embodiments, the gas distribution unit 610 may be considered a top plate and in some other embodiments, it may be considered a showerhead.

The through-holes 678 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

Referring back to FIG. 6, the gas distribution unit 610 may also include a unit heater 680 that is thermally connected to the faceplate 676 such that heat can be transferred between the faceplate 676 and the unit heater 680. The unit heater 680 may include fluid conduits in which a heat transfer fluid may be flowed. Similar to above, the heat transfer fluid may be heated to a temperature range of about 20° C. and 120° C., for example. In some instances, the unit heater 680 may be used to heat the gas distribution unit 610 to prevent unwanted condensation of vapors and gases; in some such instances, this temperature may be at least about 90° C. or 120° C.

In some embodiments, the gas distribution unit 610 may include a second unit heater 682 that is configured to heat the faceplate 676. This second unit heater 682 may include one or more resistive heating elements, fluid conduits for flowing a heating fluid, or both. Using two heaters 680 and 682 in the gas distribution unit 610 may enable various heat transfers within the gas distribution unit 610. This may include using the first and/or second unit heaters 680 and 682 to heat the faceplate 676 in order to provide a temperature-controlled chamber, as described above, in order to reduce or prevent unwanted condensation on elements of the gas distribution unit 610.

The apparatus 600 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 680 that flows the heat transfer fluid through fluid conduits may be used to cool the substrate 618 by transferring heat away from the faceplate 676 that is transferred from the substrate 618. A substrate 618 may therefore be cooled by positioning it in close proximity to the faceplate 676, such as by a gap 686 of less than or equal to 5 mm or 2 mm, such that the heat in the substrate 618 is radiatively transferred to the faceplate 676, and transferred away from the faceplate 676 by the heat transfer fluid in the first unit heater 680. The faceplate 676 may therefore be considered a heat sink for the substrate 618 in order to cool the substrate 618.

In some embodiments, the apparatus 600 may further include a cooling fluid source 673 which may contain a cooling fluid (a gas or a liquid), and a cooler (not pictured) configured to cool the cooling fluid to a desired temperature, such as less than or equal to at least about 90° C., at least about 70° C., at least about 50° C., at least about 20° C., at least about 10° C., at least about 0° C., at least about −50° C., at least about −100° C., at least about −150° C., at least about −190° C., at least about −200° C., or at least about −250° C., for instance. The apparatus 600 includes piping to deliver the cooling fluid to the one or more fluid inlets 670, and the gas distribution unit 610 which is configured to flow the cooling fluid onto the substrate. In some embodiments, the fluid may be in liquid state when it is flowed to the processing chamber 602 and may turn to a vapor state when it reaches the chamber interior 614, for example if the chamber interior 614 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In some embodiments, the flow rate of the cooling fluid into the chamber interior 614 may be at least about 0.25 liters per minute, at least about 0.5 liters per minute, at least about 1 liters per minute, at least about 5 liters per minute, at least about 10 liters per minute, at least about 50 liters per minute, or at least about 100 liters per minute, for example. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 600 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

The apparatuses provided herein can therefore rapidly heat and cool a substrate. FIG. 9 provides an example temperature control sequence. At time 0, the substrate is at approximately 20 or 25° C., and the LEDs of the substrate heater provided herein emit the visible light having wavelengths between 400 nm and 800 nm and cause the substrate temperature to rise to about 400° C. in approximately 30 seconds. This heating was accomplished using between 1 kW and 2 kW of heating power that is provided by approximately 9 kW of supplied power to the substrate heater. From about 30 seconds to about 95 seconds, the substrate heater 622 held the substrate at 400° C. using less power, such as 0.3 to about 0.5 kW of heating power provided by approximately 2 kW of supplied power. For about 30 to 60 seconds, the substrate was actively cooled using both cooling gas flowed onto the substrate (e.g., hydrogen or helium) and heat transfer to the faceplate. Once cooled, the substrate heater heated the substrate to hold its temperature at approximately 70° C. using between about 10 and 30 W of heating power provided by about 100 W of supplied power. Various processing techniques may use this type of sequence, either once or repeatedly, for processing a substrate.

In some embodiments, the apparatus 600 may include a mixing plenum for blending and/or conditioning process gases for delivery before reaching the fluid inlets 670. One or more mixing plenum inlet valves may control introduction of process gases to the mixing plenum. In some other embodiments, the gas distribution unit 610 may include one or more mixing plenums within the gas distribution unit 610. The gas distribution unit 610 may also include one or more annular flow paths fluidically connected to the through-holes 678 which may equally distribute the received fluid to the through-holes 678 in order to provide uniform flow onto the substrate.

Apparatus 600 includes a controller 631, which may be the same as controller 631 and which may include one or more physical or logical controllers, that is communicatively connected with and that controls some or all of the operations of a processing chamber, and is able to perform any of the processes described herein. Controller 631 may include one or more memory devices 633 and one or more processors 635.

Transferring the wafer is further explained with FIG. 8 which depicts a first example processing apparatus according to disclosed embodiments. Additional features of tool 800 will be discussed in greater detail below, and various features are discussed here with respect to some of the described techniques. Tool 800 includes a first processing chamber 802, a second processing chamber 804, and a third processing chamber 806. In some implementations, the first processing chamber 802 is configured to perform etching operations on a wafer, such as RIE or other ion-assisted etching, and the second processing chamber 804 is configured to perform thermal etching, including thermal ALE. The second processing chamber 804 also includes a plurality of processing stations, four stations 880A-D, that each may process a wafer. The first and second processing chambers 802 and 804 may be considered etching chambers. The third processing chamber 806 is configured to perform deposition on the wafer and may be considered a deposition chamber. The third processing chamber 806 also includes a plurality of processing stations, four stations 882A-D, that each may process a wafer. The second and third processing chambers 804 and 806 may be considered multi-station processing chambers.

The tool 800 also includes a wafer transfer unit is configured to transport one or more wafers within the tool 800. For example, after a wafer has been etched in the first processing chamber 802, the wafer transfer unit is able to transfer the wafer from the first processing chamber 802, to the second processing chamber 804 where thermal etching described herein may be performed on one or more wafers. Following this thermal etching in the second processing chamber 804, the wafer transfer unit may transfer one or more wafers from the second processing chamber 804 to the third processing chamber 806 where one or more layers of encapsulation material may be deposited on one or more wafers.

In the depicted illustration of FIG. 8, the wafer transfer unit includes a first robotic arm unit 808 in a first wafer transfer module 810 and a second robotic arm unit 812 in a second wafer transfer module 814. The first robotic arm unit 808 is configured to transport a wafer between the first processing chamber 802 and the second robotic arm unit 812, and the second robotic arm unit 812 is configured to transport the wafer between the first robotic arm unit 808, the second processing chamber 804, and the third processing chamber 806. In one implementation, each robotic arm unit 808 and 812 may have one arm, and in another implementation, they may each have two arms, where each arm has an end effector to pick substrates for transport. Front-end robot 820, in atmospheric transfer module (ATM) 822, e.g., equipment front end module (EFEM), may be used to transfer substrates from a cassette or Front Opening Unified Pod (FOUP) 824 to airlock 818.

The first and second wafer transfer modules may each be a vacuum transfer module (VTM). Airlock 818, also known as a loadlock or transfer module, is shown and may be individually optimized to perform various fabrication processes. The tool 800 also includes a pressure unit 816 that is configured to lower the pressure of the tool 800 to a vacuum or low pressure, e.g., between about 1 mTorr and about 10 Torr, and maintain the tool 800 at this pressure. This includes maintaining the first, second and third processing chambers 802-1006, the first wafer transfer module 810, and the second robotic arm unit 812 at the vacuum or low pressure.

As the wafer is transferred throughout the tool, it is able to be within an environment that is maintained at the vacuum or low pressure. For example, as the wafer is transferred from the first processing chamber 802, into the first wafer transfer module 810, to the second wafer transfer module 814, to the second processing chamber 804, the wafer is exposed to and maintained at the vacuum or low pressure, and therefore not exposed to atmospheric pressure. Similarly, as the wafer is transferred from the second processing chamber 804, to the second wafer transfer module 814, and to the third processing module 806, the wafer is maintained at the vacuum or low pressure and not exposed to atmospheric pressure.

In a further example, a substrate is placed in one of the FOUPs 824 and the front-end robot 820 transfers the substrate from the FOUP 824 to an aligner, which allows the substrate to be properly centered before it is etched, or deposited upon, or otherwise processed. After being aligned, the substrate is moved by the front-end robot 820 into an airlock 818. Because airlock modules have the ability to match the environment between an ATM and a VTM, the substrate is able to move between the two pressure environments without being damaged. From the airlock 818, the substrate is moved by the first robot arm unit 808 through the first wafer transfer module 810, or VTM 810, and into the first processing chamber 802. In order to achieve this substrate movement, the first robot arm unit 808 uses end effectors on each of its arms.

In some of the implementations that use the tool 800 of FIG. 8, etching operations may be performed in more than one processing chamber. For example, etching operations may be performed in processing chamber 802, such as RIE or other ion-assisted etching, while thermal etching, such as thermal ALE, may be performed in a different processing chamber, such as the second processing chamber 804. Using two different etching processing chambers may enable the use of different etching techniques on the wafer. For instance, thermal atomic layer etching may be performed in the first processing chamber 802 and the thermal etching cleaning operations may be performed in the second processing chamber 804.

In some embodiments, instead of using the RIE etching or other ion-assisted etching to remove the material from the substrate surface, thermal etching may be used to etch the material. The techniques for thermal etching of material may be the same as provided above except that cleaning operations may be unnecessary because no RIE or ion-assisted etching is performed. Following the thermal etching, the wafer may be transferred to a deposition chamber where an encapsulation material is deposited thereon.

Some the thermal etching provided herein may include etching multiple layers, such as concurrently etching the multiple layers of material. This may include multiple layers located within stacks of material. For example, the wafer may have a plurality of trenches, holes, or vias that each have sidewalls with multiple layers of material and differing geometries. In order to form various devices, a material may be deposited into these trenches, holes, or vias and with the isotropic nature of the thermal etching described herein, the material can be etched within the various structures.

Various apparatuses may be used to perform thermal etching. For example, in tool 800 of FIG. 8, the second processing chamber 804 may be used for this thermal etching and the third processing chamber 806 may be used for depositing the encapsulation material. In another example, an apparatus with two processing chambers may be used. FIG. 9 depicts a second example processing apparatus according to disclosed embodiments. Tool 900 includes a first processing chamber 902 and a second processing chamber 904. This tool 900 does not include the tool 800 of FIG. 8. The first processing chamber 902 includes a plurality of processing stations, four stations 980A-D, that each may process a wafer. The first processing chamber 902 is configured to perform thermal etching operations on the wafers, including thermal etching, such as thermal ALE, of the material. The second processing chamber 904 is configured to perform deposition on the wafer and may be considered a deposition chamber. The second processing chamber 904 also includes a plurality of processing stations, four stations 982A-D, that each may process a wafer. The first and second processing chambers 902 and 904 may be considered multi-station processing chambers. Processing chambers 902 and 904 may be, in some embodiments, the same as the processing chambers 804 and 806 of FIG. 8.

Tool 900 also includes a wafer transfer unit configured to transport one or more wafers within the tool 900. Additional features of tool 900 will be discussed in greater detail below, and various features are discussed here with respect to some of the described techniques. In the depicted illustration, the wafer transfer unit includes a first robotic arm unit 908 in a first wafer transfer module 910 and a second robotic arm unit 912 in a second wafer transfer module 914 that may be considered an equipment front end module (EFEM) configured to received containers for wafers, such as a front opening unified module (FOUP) 916. The first robotic arm unit 908 is configured to transport a wafer between the first processing chamber 902 and the second processing chamber 904, and between the second the second robotic arm unit 912. The second robotic arm unit 912 is configured to transport the wafer between a FOUP and the first robotic arm unit 908. After a wafer has been etched using thermal etching, such as thermal ALE, in the first processing chamber 902, the wafer transfer unit is able to transfer the wafer from the first processing chamber 902, to the second processing chamber 904 where one or more layers of encapsulation material may be deposited on one or more wafers.

Similar to above, the first transfer module 910 may a vacuum transfer module (VTM). Airlock 920, also known as a loadlock or transfer module, is shown and may be individually optimized to perform various fabrication processes. The tool 900 also includes a FOUP 916 that is configured to lower the pressure of the tool 900 to a vacuum or low pressure, e.g., between about 1 mTorr and about 10 Torr, and maintain the tool 900 at this pressure. This includes maintaining the first and second processing chambers 902 and 904, and the first wafer transfer module 910 at the vacuum or low pressure. The second wafer transfer module 914 may be at a different pressure, such as atmospheric. As the wafer is transferred throughout the tool 900, it is therefore maintained at the vacuum or low pressure. For example, as the wafer is transferred from the first processing chamber 902, into the first wafer transfer module 910, and to the second processing chamber 904, the wafer is maintained at the vacuum or low pressure and not exposed to atmospheric pressure. In a further example, a substrate is placed in one of the FOUPs 918 and the second robot arm unit 912, or front-end robot, transfers the substrate from the FOUP 918 to an aligner, which allows the substrate to be properly centered before it is etched, or deposited upon, or otherwise processed. After being aligned, the substrate is moved by the second robotic arm unit 912 into the airlock 920. Because airlock modules have the ability to match the environment between an ATM and a VTM, the substrate is able to move between the two pressure environments without being damaged. From the airlock 920, the substrate is moved by the first robot arm unit 908 through the first wafer transfer module 910, or VTM 910, and into the first processing chamber 902. In order to achieve this substrate movement, the first robot arm unit 908 uses end effectors on each of its arms.

### EXPERIMENTAL

### Experiment 1

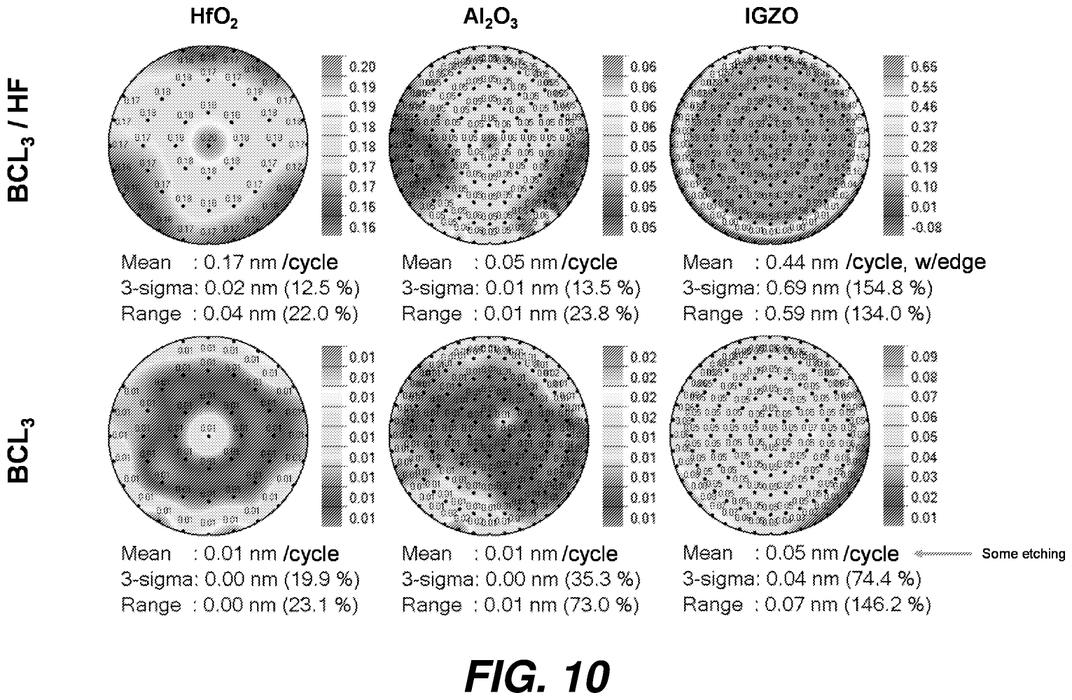

An experiment was conducted at 60 mTorr using substrate temperatures of 250° C. for 20 cycles of atomic layer etching exposures. Blanket wafers including hafnium oxide, aluminum oxide, and indium gallium zinc oxide (IGZO) were exposed to boron trichloride with hydrogen fluoride, and to boron trichloride without hydrogen fluoride. Blanket wafers including hafnium oxide, aluminum oxide, and indium gallium zinc oxide were exposed to dimethylaluminum chloride (DMAC). The etch rates per cycle for using boron trichloride were greater than those of DMAC for hafnium oxide and IGZO and the etch rate per cycle for using boron trichloride was smaller than that of DMAC for aluminum oxide. Using boron trichloride alone did not result in substantial etching of aluminum oxide and hafnium oxide. Using boron trichloride alone resulted in some minor etching of IGZO with an etch rate that was roughly an order of magnitude smaller compared to using HF/BCL₃ (FIG. 10).

### Experiment 2

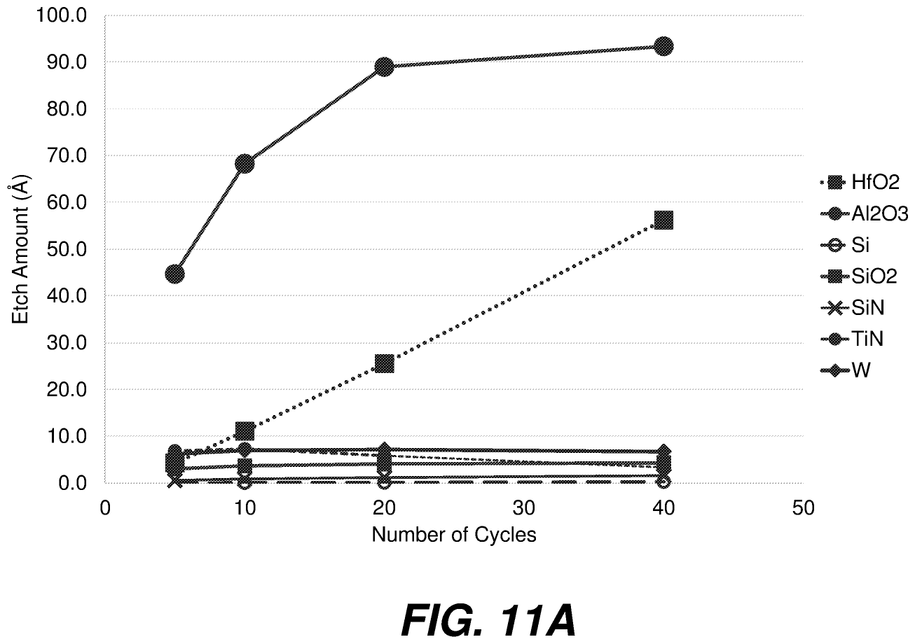

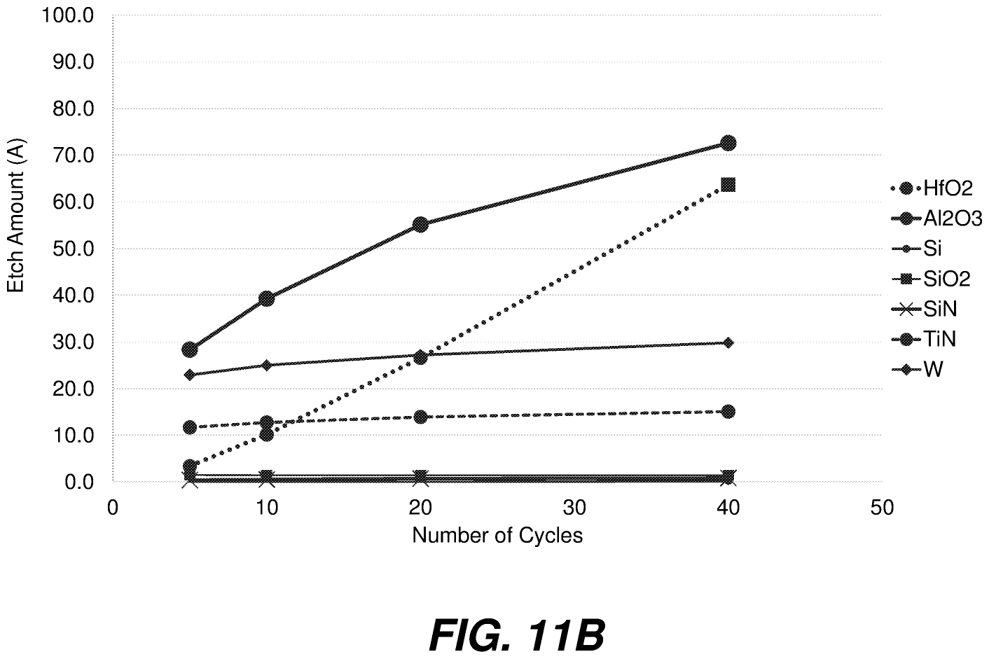

An experiment was conducted at 275° C. at 110 mTorr for 5, 10, 20, and 40 cycles of atomic layer etching exposures. Blanket wafers including hafnium oxide, aluminum oxide, silicon, silicon dioxide, silicon nitride, titanium nitride, and tungsten were exposed to hydrogen fluoride and dimethylaluminum chloride (DMAC) in cyclic ALE. The etch amounts were measured after 5, 10, 20, and 40 cycles and are graphed in FIG. 11A. Blanket wafers including hafnium oxide, aluminum oxide, silicon, silicon dioxide, silicon nitride, titanium nitride, and tungsten were exposed to boron trichloride in cyclic ALE. The etch amounts were measured after 5, 10, 20, and 40 cycles and are graphed in FIG. 11B.

Using boron trichloride achieved greater etching for aluminum oxide at 5, 10, 20, and 40 cycles of ALE. Using boron trichloride achieved relatively similar etching for hafnium oxide but such results also indicated viability of using boron trichloride during etching. Etching using boron trichloride was also effective for several other materials as shown.

Table 1 summarizes the etch amounts for ALE using DMAC versus BCl₃. Table 2 summarizes the etch per cycle and selectivity relative to hafnium oxide for ALE using DMAC versus BCl₃.

TABLE 1
Etch amounts per 5, 10, 20, and
40 cycles for DMAC and BCl₃ ALE

| | | Etch Amount (Å) | | | | | | |
|---|---|---|---|---|---|---|---|---|
| Etchant | Cycles | HfO₂ | Al₂O₃ | Si | SiO₂ | SiN | TiN | W |
| DMAC | 5* | 4.2 | 44.7 | −0.1 | 3 | 0.6 | 6.8 | 6.2 |
| | 10 | 11 | 68.3 | 0 | 3.6 | 0.8 | 7.3 | 7 |
| | 20 | 25.5 | 88.9 | 0.1 | 4.1 | 1.1 | 5.8 | 7.1 |
| | 40 | 56.2 | 93.3 | 0.3 | 4.3 | 1.5 | 3.3 | 6.7 |
| BCl₃ | 5* | 3.4 | 28.3 | 0 | 1.5 | 0.4 | 11.7 | 22.9 |
| | 10 | 10.2 | 39.3 | 0 | 1.4 | 0.5 | 12.8 | 25 |
| | 20 | 26.6 | 55.1 | 0 | 1.4 | 0.7 | 13.9 | 27.2 |
| | 40 | 63.7 | 72.6 | 0.2 | 1.4 | 0.8 | 15.1 | 29.8 |

*Represents initial loss

TABLE 2
Etch per Cycle and Selectivity for DMAC and BCl₃ Etchants in ALE

| Property | Etchant | HfO₂ | Al₂O₃ | Si | SiO₂ | SiN | TiN | W |
|---|---|---|---|---|---|---|---|---|
| Etch/Cycle (Å) | DMAC | 1.5 | 0.7 | 0 | 0 | 0 | 0 | 0 |
| | BCl₃ | 1.8 | 1.1 | 0 | 0 | 0 | 0.1 | 0.2 |
| Selectivity | DMAC | x | 2 | >200 | 78 | 65 | >100 | >100 |
| relative to HfO₂ | BCl₃ | x | 1.7 | >200 | >100 | >100 | 24 | 11 |

### CONCLUSION

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes certain disclosed embodiments are implemented on a wafer. However, the certain disclosed embodiments are not so limited. The work piece may be of various shapes, sizes, and materials. In addition to semiconductor wafers, other work pieces that may take advantage of this invention include various articles such as printed circuit boards, magnetic recording media, magnetic recording sensors, mirrors, optical elements, micro-mechanical devices and the like. Certain disclosed embodiments may also be relevant for recycling certain materials out of a mix of waste products. For example, in some embodiments, certain disclosed embodiments may be used to remove certain precious metals without substantially removing other materials.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1-11. (canceled)

12. An apparatus for semiconductor processing, the apparatus comprising:
a first processing chamber that includes a first interior and a first processing station having a first wafer support configured to support a wafer in the first interior, and a first wafer heating unit configured to heat the wafer supported by the first wafer support;
a process gas unit configured to flow:
a first chemical species comprising fluorine onto the wafer at the first processing station in the first processing chamber, and
boron trichloride onto the wafer at the first processing station in the first processing chamber; and
a controller with instructions that are configured to:
cause a wafer to be provided to the first processing station in the first processing chamber, the wafer having a layer of a chalcogenide material,
cause the first wafer heating unit to heat the wafer to a first temperature, and
cause etching of a material on the wafer by modifying a surface of the material by causing the process gas unit to flow the first chemical species onto the wafer at the first processing station of the first processing chamber to create a modified layer while the wafer is at the first temperature, and removing the modified layer, without using a plasma, by causing the process gas unit to flow the boron trichloride onto the wafer at the first processing station of the first processing chamber.

13. A method for processing wafers, the method comprising:
providing a wafer to a processing chamber, the wafer having a material to be etched;
exposing the material to be etched to a halogen-containing gas to form a modified layer on a surface of the wafer; and
exposing the modified layer to boron-and-chlorine-containing gas to remove the modified layer from the surface of the wafer.

14. The method of claim 13, wherein exposing the modified layer is performed in a plasma-less environment.

15. The method of claim 13, wherein exposing the material to be etched to the halogen-containing gas comprises igniting the halogen-containing gas to form a halogen-containing plasma.

16. The method of claim 13, wherein exposing the modified layer forms a volatile oxychloride, or causes a ligand exchange, or both.

17. The method of claim 13, wherein exposing the material to be etched to the halogen-containing gas and exposing the modified layer are performed in alternating pulses by atomic layer etching.

18. The method of claim 13, wherein the material to be etched comprises a metal oxide.

19. The method of claim 13, wherein the material to be etched comprises a tungsten-free material.

20. The method of claim 18, wherein the metal oxide comprises a metal selected from the group consisting of aluminum, silicon, germanium, antimony, indium, zirconium, selenium, tin, gallium, zinc, molybdenum, hafnium, tellurium, and combinations thereof.

21. The method of claim 13, wherein the material to be etched comprises an oxygen-containing material.

22. The method of claim 21, wherein the oxygen-containing material is selected from the group consisting of zirconium oxide, hafnium oxide, and hafnium zirconium oxide.

23. The method of claim 13, wherein the material to be etched is a carbide or nitride formed by oxidizing the carbide or nitride.

24. The method of claim 13, wherein the material to be etched is doped.

25. The method of claim 13, wherein the halogen-containing gas comprises fluorine.

26. The method of claim 21, wherein the halogen-containing gas comprises hydrogen fluoride.

27. The method of claim 21, wherein the halogen-containing gas comprises nitrogen trifluoride.

28. The method of claim 13, wherein the boron-and-chlorine-containing gas comprises boron trichloride.

29. The method of claim 13, wherein forming the modified layer and removing the modified layer are performed without breaking vacuum.

30. A method for processing wafers, the method comprising:
providing a wafer to a processing chamber, the wafer having an oxygen-containing material;
exposing the oxygen-containing material to a halogen-containing gas to form a modified oxygen-containing layer on a surface of the wafer; and
exposing the modified oxygen-containing layer to boron trichloride to remove the modified layer from the surface of the wafer.

31. The method of claim 30, wherein exposing the modified layer is performed in a plasma-less environment.
